(19) United States
(12) Patent Application Publication
(10) Pub. No.: US 2021/0280817 A1
(43) Pub. Date: Sep. 9, 2021

(54) DISPLAY MODULES WITH LASER WELD SEALS AND MODULAR DISPLAY

(71) Applicant: CORNING INCORPORATED, Corning, NY (US)

(72) Inventors: Stephan Lvovich LOGUNOV, Corning, NY (US); James Edward McGINNIS, Watkins Glen, NY (US); Mark Alejandro QUESADA, Horseheads, NY (US); Alexander Mikhailovich STRELTSOV, Corning, NY (US)

(73) Assignee: Corning Incorporated, Corning, NY (US)

(21) Appl. No.: 16/326,429

(22) PCT Filed: Aug. 15, 2017
(86) PCT No.: PCT/US2017/046893

§ 371 Date: Feb. 19, 2019

Related U.S. Application Data
(60) Provisional application No. 62/377,991, filed on Aug. 22, 2016.

(51) Int. Cl. H01L 51/52; H01L 51/56; B23K 26/324

(52) U.S. Cl. CPC H01L 51/5246; B23K 2103/56; B23K 26/324; H01L 51/56

(57) ABSTRACT

In some embodiments, an apparatus comprises at least one module. Each module comprises a first substrate, and a second substrate disposed over the first substrate. The module has a periphery. The module includes an array of pixels disposed between the first substrate and the second substrate, and inside the periphery. Each pixel has an active area and an inactive area. The array of pixels a first intra-modular separation distance between the active area of adjacent pixels in a first direction. A laser weld hermetically seals the first substrate to the second substrate along a portion of the periphery. The laser weld is disposed between the active area of the pixels and the periphery. The distance between the active area of the pixels and the periphery in the first direction is not more than 50% of the first intra-modular separation distance. Methods of making the apparatus are also described.

### BACKGROUND

This application claims the benefit of priority under 35 U.S.C. § 120 of U.S. Application Ser. No. 62/377,991 filed on Aug. 22, 2016, the content of which is relied upon and incorporated herein by reference in its entirety.

### FIELD

The present disclosure relates to display technology.

### BACKGROUND

OLEDs, hybrid QD-OLEDs, or QD-LED based TV-displays are preferably hermetically sealed. This is because such devices require a scrupulously oxygen & moisture free environment for proper operation and commercially viable lifetimes. Frit seals may be used for such hermetic operation. While frit-sealed devices have some desirable properties, they are limited in size due to large stress-buildup occurring over the long frit seals of TV displays that tend to compromise hermeticity over time. This phenomenon has limited widespread usage of OLEDs to small displays, and mobile handheld devices.

### BRIEF SUMMARY

In some embodiments, the present disclosure is directed to a display module having peripheral laser welds, a display made up of multiple such modules, and related methods.

In some embodiments, an apparatus comprises at least one module. Each module comprises a first substrate, and a second substrate disposed over the first substrate. The module has a periphery. The module includes an array of pixels disposed between the first substrate and the second substrate, and inside the periphery. Each pixel has an active area and an inactive area. The array of pixels has a first intra-modular separation distance between the active area of adjacent pixels in a first direction. A laser weld hermetically seals the first substrate to the second substrate along a portion of the periphery. The laser weld is disposed between the active area of the pixels and the periphery. The distance between the active area of the pixels and the periphery in the first direction is not more than 50% of the first intra-modular separation distance.

In some embodiments, along the portion of the periphery, the entire width of the laser weld may be within 500 μm of the periphery, within 200 μm of the periphery, or within 100 μm of the periphery.

In some embodiments, along the portion of the periphery, the distance between the laser weld and the active area of the array of pixels is at least 50% of the width of the laser weld, at least 100% of the width of the laser weld, or at least 200% of the width of the laser weld.

In some embodiments, along the portion of the periphery, the laser weld has a width less than 500 μm, less than 200 μm, or less than 100 μm.

In some embodiments, along the portion of the periphery, the distance between the laser weld and the periphery is not more than 50 μm.

In some embodiments, along the portion of the periphery, the laser weld directly bonds the first substrate to the second substrate.

In some embodiments, the portion of the periphery is the entire periphery.

In some embodiments, each module is a rectangle having a first linear edge and a third linear edge in the first direction, and a second linear edge and a fourth linear edge in a second direction perpendicular to the first direction. The array of pixels comprises an array of light emitting devices having the first intra-modular separation distance in the first direction, and a second intra-modular separation distance in the second direction.

In some embodiments, the first intra-modular separation distance is not more than 2000 μm, and the second intra-modular separation distance is not more than 2000 μm. Along the second and fourth linear edges, the distance between the periphery and the active area of the array of pixels in the first direction is not more than 1000 μm. Along the first and third linear edges, the distance between the periphery and the active area of the array of pixels in the second direction is not more than 1000 μm. This and other desirable parameters are described in the following paragraph.

In some embodiments, the first and second intra-modular separation distances are the same. Desirable ranges for intra-modular separation distances in both the first and second directions include not more than 2000 μm, not more than 1500 μm, not more than 1250 μm, not more than 1000 μm, not more than 750 μm, not more than 500 μm, and not more than 300 μm. It is desirable that, along the second and fourth linear edges, the distance between the periphery and the active area of the array of pixels in the first direction is not more than half the intra-modular separation distance in the first direction, and that, along the first and third linear edges, the distance between the periphery and the active area of the array of pixels in the second direction is not more than half the intra-modular separation distance in the first direction. So, desirable ranges for the distance between the periphery and the active area of the array of pixels in the first direction and the second direction include not more than 1000 μm, not more than 750 μm, not more than 625 μm, not more than 500 μm, not more than 375 μm, not more than 250 μm, and not more than 150 μm.

In some embodiments, the at least one module includes a first module and a second module. The first module is joined to the second module along the second linear edge of the first module and the fourth linear edge of the second module. An inter-modular separation distance between the active area of a pixel of the first module and the active area of adjacent pixel of the second module in the first direction is not more than 20% different than the intra-modular separation distance of the first module in the first direction and the intra-modular separation distance of the second module in the first direction.

In some embodiments, the apparatus comprises a display. The display comprises a two dimensional array of the modules. A two dimensional array of pixels is spread across the two dimensional array of modules. The two dimensional array of pixels has a plurality of rows in the first direction and a plurality of columns in the second direction. In each row, in the first direction, the separation distance between the active area of each pair of adjacent pixels, whether inter-modular or intra-modular, is not more than 10% different than the average inter-modular separation distance. In each column, in the second direction, the separation distance between the active area of each pair of adjacent pixels, whether inter-modular or intra-modular, is not more than 10% different than the average inter-modular separation distance. For each line along which two modules are joined, the separation distance between the active area of adjacent pixels across the line in a first direction perpendicular to the line is not more than 10% different from the average separation distance between the active area of pixels within each of the two modules in the first direction.

In some embodiments, the separation distance between the light emitting devices within a pixel in a first direction is 10 to 400 μm.

In some embodiments, the module is a rectangle, and each side of the rectangle has a length less than 10 cm.

In some embodiments, the apparatus includes only one module. The one module includes only one first substrate and one second substrate.

In some embodiments, a plurality of electrical connections is formed through the first substrate to the array of light emitting devices.

In some embodiments, a plurality of electrical connections from the periphery of the module to the array of light emitting devices.

In some embodiments, the light emitting devices are selected from the group consisting of: organic light emitting devices, hybrid quantum dot organic light emitting devices, and quantum dot organic light emitting devices.

In some embodiments, a method is provided, the method comprising laser welding a second substrate having a periphery to a first substrate by forming at least one laser weld between the second substrate and the first substrate. Along at least a portion of the periphery, the entire width of the laser weld is within 500 μm of the periphery. An array of light emitting devices is disposed between the first substrate and the second substrate, and inside the periphery.

In some embodiments, a method includes a thin UV absorbing film on the first substrate or the second substrate absorbs UV laser energy during the welding process.

In some embodiments, a method includes at least one of the first substrate or the second substrate absorbs sufficient UV laser energy during the laser process to form the laser weld.

In some embodiments, the method includes laser welding to hermitically seals the array of light emitting devices between the first substrate and the second substrate. The laser weld extends along the entire periphery, and is within 500 μm of the periphery along the entire periphery.

### BRIEF DESCRIPTION OF THE DRAWINGS

The accompanying figures, which are incorporated herein, form part of the specification and illustrate embodiments of the present disclosure. Together with the description, the figures further serve to explain the principles of and to enable a person skilled in the relevant art(s) to make and use the disclosed embodiments. These figures are intended to be illustrative, not limiting. Although the disclosure is generally described in the context of these embodiments, it should be understood that it is not intended to limit the scope of the disclosure to these particular embodiments. In the drawings, like reference numbers indicate identical or functionally similar elements.

FIG. 1 is a diagram of an exemplary procedure for laser welding according to an embodiment of the present disclosure.

FIG. 2 is a schematic diagram illustrating the formation of a hermetically-sealed device via laser-sealing according to one embodiment.

FIG. 3 is a diagram of another embodiment of the present subject matter.

FIG. 4 is an illustration of an experimental arrangement used to estimate physical extent of a laser welding bonding zone.

FIG. 5 is a microscopic image of fractured samples.

FIG. 6 is an illustration of an experiment assessing the extent of laser welding over ITO leads.

FIG. 7 provides photographs of laser seal lines formed over an ITO patterned film.

FIG. 8 is a series of photographs of additional laser seal lines formed over a patterned film.

FIG. 9 is a simplified diagram of another method according to some embodiments.

FIG. 10 illustrates a pixel, according to an embodiment.

FIG. 11 illustrates a pixel layout of a 55″ OLED TV with a roughly 50% “fill factor”, according to an embodiment.

FIG. 12 illustrates an array of repeating display modules, according to an embodiment.

FIG. 13A illustrates a portion of the array of display modules, according to an embodiment.

FIG. 13B illustrates a portion of the array of display modules, according to an embodiment.

FIG. 14 illustrates an array of modules forming a monochromatic display, according to an embodiment.

FIG. 15 illustrates an array of modules forming an R-G-B display, according to an embodiment.

FIG. 16A is a top view of a glass substrate depicting an array of through-via holes, according to an embodiment.

FIG. 16B is a 3D view of the glass substrate, according to an embodiment.

FIG. 17 is a cross-sectional view of an OLED element, according to an embodiment.

FIG. 18 illustrates a single module R-G-B display, according to an embodiment.

FIG. 19A is a top view of a passive-matrix OLED element, according to an embodiment.

FIG. 19B is a 3D view of a passive-matrix OLED element, according to an embodiment.

### DETAILED DESCRIPTION

Laser Welding with Interfacial UV Absorbing Film

Many modern devices require hermetic environments to operate and many amongst these are “active” devices which require electrical biasing. Displays such as organic light emitting diodes (OLED) that require light transparency and biasing are demanding applications due to their need for absolute hermeticity as a result of the use of electron-injection materials. These materials would generally decompose at atmosphere within seconds otherwise, so the respective device should maintain vacuum or inert atmospheres for long periods of time. Furthermore, the hermetic sealing should be performed near ambient temperatures due to high temperature sensitivity of the organic material to be encapsulated.

Frit-based sealants, for instance, include glass materials ground to a particle size ranging typically from about 2 μm to 150 μm. For frit-sealing applications, the glass frit material is typically mixed with a negative CTE material having a similar particle size, and the resulting mixture is blended into a paste using an organic solvent or binder. Exemplary negative CTE inorganic fillers include cordierite particles (e.g. Mg₂Al₃ [AlSi₅O₁₈]), barium silicates, β-eucryptite, zirconium vanadate (ZrV₂O₇), or zirconium tungstate, (ZrW₂O₈) and are added to the glass frit, forming a paste, to lower the mismatch of thermal expansion coefficients between substrates and the glass frit. The solvents are used to adjust the rheological viscosity of the combined powders and organic binder paste and must be suitable for controlled dispensing purposes. To join two substrates, a glass frit layer can be applied to sealing surfaces on one or both of the substrates by spin-coating or screen printing. The fit-coated substrate(s) are initially subjected to an organic burn-out step at relatively low temperature (e.g., 250° C. for 30 minutes) to remove the organic vehicle. Two substrates to be joined are then assembled/mated along respective sealing surfaces and the pair is placed in a wafer bonder. A thermo-compressive cycle is executed under well-defined temperature and pressure whereby the glass frit is melted to form a compact glass seal. Glass frit materials, with the exception of certain lead-containing compositions, typically have a glass transition temperature greater than 450° C. and thus require processing at elevated temperatures to form the barrier layer. Such a high-temperature sealing process can be detrimental to temperature-sensitive workpieces. Further, the negative CTE inorganic fillers, which are used in order to lower the thermal expansion coefficient mismatch between typical substrates and the glass frit, will be incorporated into the bonding joint and result in a frit-based barrier layer that is substantially opaque. Based on the foregoing, it would be desirable to form glass-to-glass, glass-to-metal, glass-to-ceramic, and other seals at low temperatures that are transparent and hermetic.

While conventional laser welding of glass substrates can employ ultra-high laser power devices, this operation at near laser ablation often times damages the glass substrates and achieves a poor quality hermetic seal. Again, such conventional methods increase the opacity of the resulting device and also provide a low quality seal.

Some embodiments of the present disclosure are generally directed to hermetic barrier layers, and more particularly to methods and compositions used to seal solid structures using absorbing thin films. Some embodiments of the present disclosure provide a laser welding or sealing process of a glass sheet with other material sheets using a thin film with absorptive properties during sealing process as an interfacial initiator. Exemplary laser-welding conditions according to some embodiments can be suitable for welding over interfacial conductive films with negligible reduction in the conductivity. Some embodiments may thus be employed to form hermetic packages of active devices such as OLEDs or other devices and enable widespread, large-volume fabrication of suitable glass or semiconductor packages. It should be noted that the terms sealing, joining, bonding, and welding can be and are used interchangeably in the instant disclosure. Such use should not limit the scope of the claims appended herewith. It should also be noted that the terms glass and inorganic as they relate to the modification of the noun film can be used interchangeably in this instant disclosure, and such use should not limit the scope of the claims appended herewith.

Some embodiments of the present disclosure provide a laser sealing process, e.g., laser welding, diffusing welding, etc., that can provide an absorptive film at the interface between two glasses. The absorption in steady state may be greater than or as high as about 70% or may be less than or as low as about 10%. The latter relies upon color center formation within the glass substrates due to extrinsic color centers, e.g., impurities or dopants, or intrinsic color centers inherent to the glass, at an incident laser wavelength, combined with exemplary laser absorbing films. Some non-limiting examples of films include SnO₂, ZnO, TiO₂, ITO, UV absorbing glass films with Tg<600° C., and low melting glass (LMG), or low liquidus temperature (LLT) films (for materials without a glass transition temperature) which can be employed at the interface of the glass substrates. LLT materials may include, but are not limited to, ceramic, glass-ceramic, and glass materials to name a few. LLT glass, for example, can include tin-fluorophosphate glass, tungsten-doped tin fluorophosphate glass, chalcogenide glass, tellurite glass, borate glass and phosphate glass. In another non-limiting embodiment, the sealing material can be a Sn²⁺ containing inorganic oxide material such as, for example, SnO, SnO+P₂O₅ and SnO+BPO₄. Additional non-limiting examples may include near infrared (NIR) absorbing glass films with absorption peaks at wavelength >800 nm. Welds using these materials can provide visible transmission with sufficient UV or NIR absorption to initiate steady state gentle diffusion welding. These materials can also provide transparent laser welds having localized sealing temperatures suitable for diffusion welding. Such diffusion welding results in low power and temperature laser welding of the respective glass substrates and can produce superior transparent welds with efficient and fast welding speeds. Exemplary laser welding processes according to embodiments of the present disclosure can also rely upon photo-induced absorption properties of glass beyond color center formation to include temperature induced absorption.

The phenomenon of welding transparent glass sheets together with a laser using an interfacial thin film of low melting inorganic (LMG) material or ultraviolet absorbing (UVA) or infrared absorbing (IRA) material to initiate sealing is described herein. In some embodiments, three criteria are described for realizing strong bond formation: (1) exemplary LMG or UVA or IRA films can absorb at an incident wavelength outside of window of transparency (from about 420 nm to about 750 nm) sufficient to propagate sufficient heat into the glass substrate, and the glass substrate can thus exhibit (2) temperature-induced-absorption and (3) transient color-center formation at the incident wavelength. Measurements suggest that a thermo-compressive diffusion welding mechanism is formed, qualitatively resulting in a very strong bond formation. The unfolding of temperature events related to the welding process and clear prevalence of color center formation processes in laser welding are also described herein. CTE-mismatch irrelevance between the LMG or UVA material and Eagle XG® materials and post-weld strength enhancement after thermal cycling to 600° C. are also discussed. Some embodiments involve the welding of glass sheets together that have different thicknesses by using thermally conductive plates. Some embodiments can thus provide an ability to form hermetic packages, with both passive and active devices that can include laser sealing attributes associated with using LMG or UVA interfacial materials. Exemplary attributes include, but are not limited to, transparent, strong, thin, high transmission in the visible spectrum, “green” composition, CTE-mismatch irrelevance between LMG or UVA films and glass substrates, and low melting temperatures. “Green” composition here refers to environmentally safe materials such as ZnO, LMG materials, TiO₂ etc. Hazardous materials, such as lead, mercury, cadmium or other materials on the “P-list” maintained by the US Environmental Protection Agency, are not considered “green.”

Some embodiments of the present disclosure provide a laser sealing process having a low temperature bond formation and “direct glass sealing” where the transparent glass can be sealed to absorbing glass at the incident wavelength resulting in an opaque seal at visible wavelengths 400-700 nm. In some embodiments, both glasses are transparent or almost transparent at incident laser wavelengths, and in the visible wavelength range. The resulting seal is also transparent in the visible wavelength range making it attractive for lighting applications as no light is absorbed at the seal location, and thus, no heat build-up is associated with the seal. In addition, since the film can be applied over the entire cover glass, there is no need to precision dispense sealing frit paste for the sealing operation thereby providing device manufacturers large degrees of freedom for changing their sealing pattern without need for special patterning and processing of the sealing area. In some embodiments, sealing can also be performed on certain spots of the glass area to form non-hermetic bonding for mechanical stability. Furthermore, such sealing can be performed on curved conformal surfaces.

Some embodiments of the present disclosure provide low melting temperature materials which may be used to laser-weld glass sheet together that involve welding any glass without regard to the differing CTEs of the glass. Some embodiments can provide symmetric welding (i.e., thick-to-thick) of glass substrates, e.g., Eagle-to-Eagle, Lotus-to-Lotus, etc. Some embodiments can provide asymmetric welding (i.e., thin-to-thick) of glass substrates, e.g., Willow-to-Eagle XG®, Eagle-to-Lotus (i.e., thin-to-thin), Eagle-to-Fused Silica, Willow-to-Willow, fused silica-fused silica, etc. using thermally conductive plates. Some embodiments can provide disparate substrate welding (glass to ceramic, glass to metal, etc.) and can provide transparent and/or translucent weld lines. Some embodiments can provide welding for thin, impermeable, “green”, materials and can provide strong welds between two substrates or materials having large differences in CTEs.

Some embodiments also provide materials used to laser weld glass packages together thereby enabling long lived hermetic operation of passive and active devices sensitive to degradation by attack of oxygen and moisture. Exemplary LMG or other thin absorbing film seals can be thermally activated after assembly of the bonding surfaces using laser absorption and can enjoy higher manufacturing efficiency since the rate of sealing each working device is determined by thermal activation and bond formation rather than the rate one encapsulates a device by inline thin film deposition in a vacuum or inert gas assembly line. Exemplary LMG, LLT and other thin absorbing films in UV or NIR-IR seals can also enable large sheet multiple device sealing with subsequent scoring or dicing into individual devices (singulation), and due to high mechanical integrity, the yield from singulation can be high.

In some embodiments, a method of bonding a workpiece comprises forming an inorganic film over a surface of a first substrate, arranging a workpiece to be protected between the first substrate and a second substrate wherein the film is in contact with the second substrate, and bonding the workpiece between the first and second substrates by locally heating the film with laser radiation having a predetermined wavelength. The inorganic film, the first substrate, or the second substrate can be transmissive at approximately 420 nm to approximately 750 nm.

In some embodiments, a bonded device is provided comprising an inorganic film formed over a surface of a first substrate, and a device protected between the first substrate and a second substrate wherein the inorganic film is in contact with the second substrate. In such an embodiment, the device includes a bond formed between the first and second substrates as a function of the composition of impurities in the first or second substrates and as a function of the composition of the inorganic film though a local heating of the inorganic film with laser radiation having a predetermined wavelength. Further, the inorganic film, the first substrate, or the second substrate can be transmissive at approximately 420 nm to approximately 750 nm.

In some embodiments, a method of protecting a device is provided comprising forming an inorganic film layer over a first portion surface of a first substrate, arranging a device to be protected between the first substrate and a second substrate wherein the sealing layer is in contact with the second substrate, and locally heating the inorganic film layer and the first and second substrates with laser radiation to melt the sealing layer and the substrates to form a seal between the substrates. The first substrate can be comprised of glass or glass-ceramics, and the second substrate can be comprised of glass, metal, glass-ceramics or ceramic.

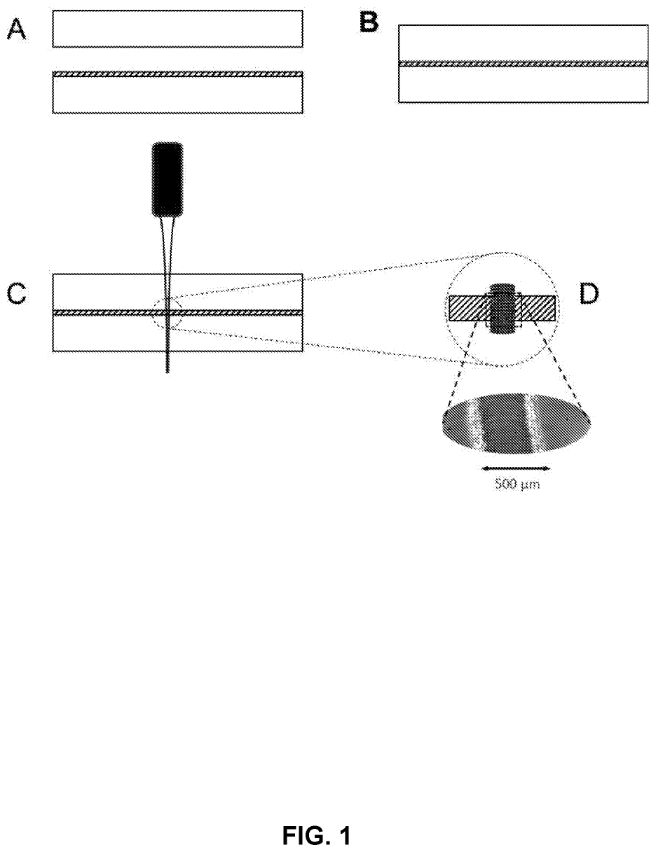

FIG. 1 is a diagram of an exemplary procedure for laser welding according to some embodiments of the present disclosure. With reference to FIG. 1, a procedure is provided for laser welding of two Eagle XG® (EXG) glass sheets or substrates together using a suitable UV laser. While two EXG glass sheets are illustrated and described, the claims appended herewith should not be so limited as any type and composition of glass substrates can laser welded using embodiments of the present disclosure. That is, methods as described herein are applicable to soda lime glasses, strengthened and unstrengthened glasses, aluminosilicate glasses, etc. With continued reference to FIG. 1, a sequence of exemplary steps in laser-welding two glass substrates together is provided whereby one substrate can be coated with a low melting glass (LMG) or ultraviolet absorbing (UVA) film material or MR absorbing (IRA) film material. In steps A to B, a top glass substrate can be pressed onto another substrate coated with an exemplary UVA, IRA or LMG film. It should be noted that many experiments and examples described herein may refer to a particular type of inorganic film (e.g., LMG, UVA, etc.). This, however, should not limit the scope of the claims appended herewith as many types of inorganic films are suitable for the welding processes described. In step C, a laser can be directed at an interface of the two glass sheets with suitably chosen parameters to initiate a welding process as illustrated in step D. The weld dimension was found to be slightly less than the dimensions of the incident beam (approximately 500 μm).

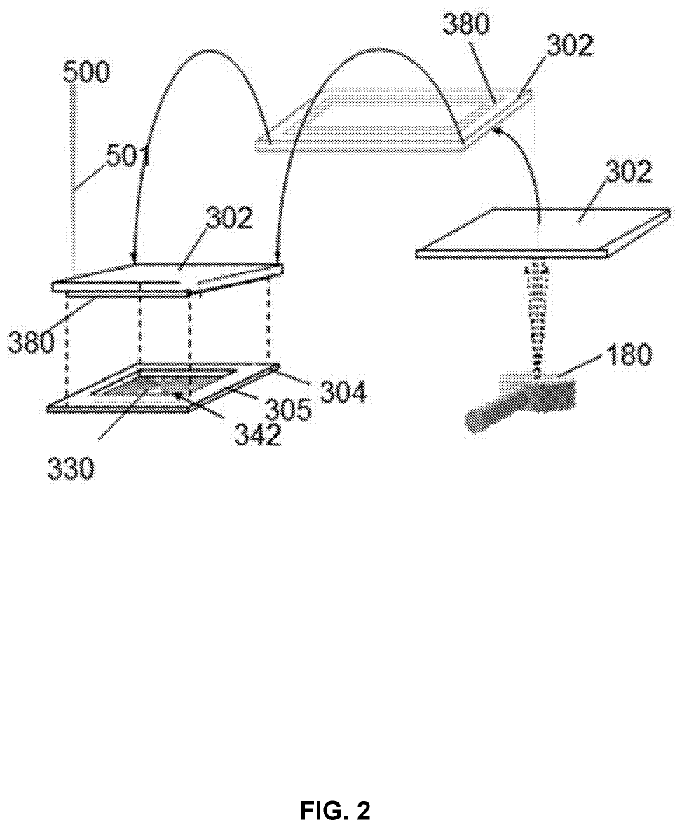

FIG. 2 is a schematic diagram illustrating the formation of a hermetically-sealed device via laser-sealing according to some embodiments. With reference to FIG. 2, in an initial step, a patterned glass layer 380 comprising a low melting temperature (e.g., low Tg) glass can be formed along a sealing surface of a first planar glass substrate 302. The glass layer 380 can be deposited via physical vapor deposition, for example, by sputtering from a sputtering target 180. In some embodiments, the glass layer can be formed along a peripheral sealing surface adapted to engage with a sealing surface of a second glass or other material substrate 304. In the illustrated embodiment, the first and second substrates, when brought into a mating configuration, cooperate with the glass layer to define an interior volume 342 that contains a workpiece 330 to be protected. In the illustrated example, which shows an exploded image of the assembly, the second substrate comprises a recessed portion within which a workpiece 330 is situated.

A focused laser beam 501 from a laser 500 can be used to locally melt the low melting temperature glass and adjacent glass substrate material to form a sealed interface. In one approach, the laser can be focused through the first substrate 302 and then translated (scanned) across the sealing surface to locally heat the glass sealing material. To affect local melting of the glass layer, the glass layer can preferably be absorbing at the laser processing wavelength. The glass substrates can be initially transparent (e.g., at least 50%, 70%, 80% or 90% transparent, or within any range having any two of these values as endpoints) at the laser processing wavelength.

In some embodiments, in lieu of forming a patterned glass layer, a blanket layer of sealing (low melting temperature) glass can be formed over substantially all of a surface of a first substrate. An assembled structure comprising the first substrate/sealing glass layer/second substrate can be assembled as above, and a laser can be used to locally-define the sealing interface between the two substrates.

The laser 500 can have any suitable output to affect sealing. An exemplary laser can be a UV laser 22, such as, but not limited to, a 355 nm laser, which lies in the range of transparency for common display glasses. A suitable laser power can range from about 1 W to about 10 W. The width of the sealed region, which can be proportional to the laser spot size, can be about 0.06 to 2 mm, e.g., 0.06, 0.1, 0.2, 0.5, 1, 1.5 or 2 mm, or within any range having any two of these values as endpoints. A translation rate of the laser (i.e., sealing rate) can range from about 1 mm/sec to 400 mm/sec or even to 1 m/sec or greater, such as 1, 2, 5, 10, 20, 50, 100, 200, or 400 mm/sec, 600 mm/sec, 800 mm/sec, 1 m/sec, or within any range having any two of these values as endpoints. The laser spot size (diameter) can be about 0.02 to 2 mm, e.g., 0.02, 0.05, 0.1, 0.2, 0.5, 1, 1.5 or 2 mm, or within any range having any two of these values as endpoints.

Suitable glass substrates exhibit significant induced absorption during sealing. In some embodiments, the first substrate 302 can be a transparent glass plate like those manufactured and marketed by Corning Incorporated under the brand names of Eagle 2000® or other glass. Alternatively, the first substrate 302 can be any transparent glass plate such as those manufactured and marketed by Asahi Glass Co. (e.g., AN100 glass), Nippon Electric Glass Co., (e.g., OA-10 glass or OA-21 glass), or Corning Precision Materials. The second substrate 304 can be the same glass material as the first glass substrate, or second substrate 304 can be a non-transparent substrate such as, but not limited to, a ceramic substrate or a metal substrate. Exemplary glass substrates can have a coefficient of thermal expansion of less than about 150×10⁻⁷/° C., e.g., less than 50×10⁻⁷, 20×10⁻⁷ or 10×10⁻⁷/° C. Of course, in some embodiments the first substrate 302 can be a ceramic, ITO, metal or other material substrate, patterned or continuous.

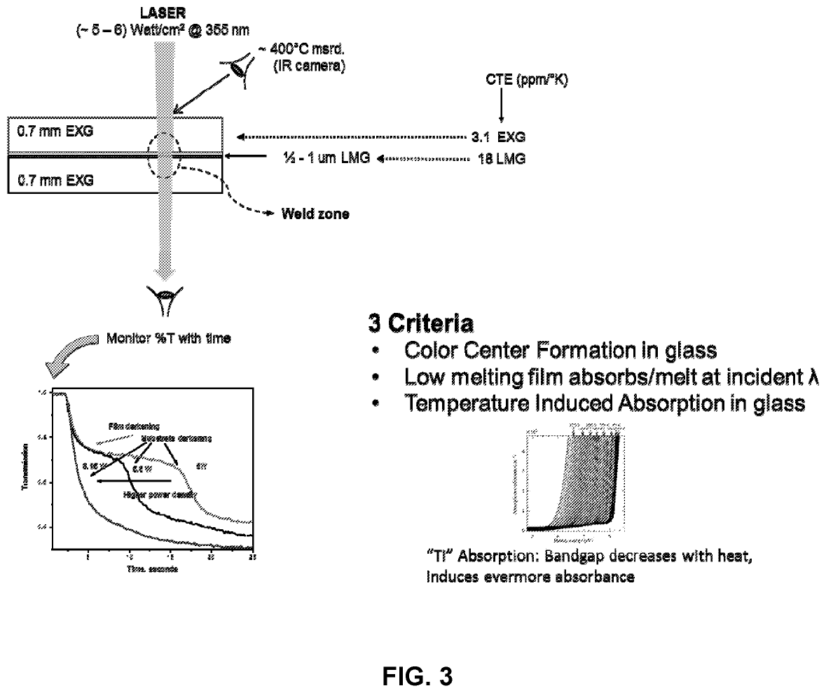

FIG. 3 is a diagram of an embodiment of the present subject matter. With reference to FIG. 3, the upper left diagram illustrates some exemplary parameters that can be employed to laser weld two Eagle XG® (EXG) glass substrates. The transmission, % T, can be monitored over time and is illustrated in the lower left graph for three different laser powers. The onset of melting of the LMG, IRA or UVA film can be readily observed in the lower laser power curves (rightmost curves) as a “knee” like inflection followed by rapid absorption and heating of the glass substrate, due to high local glass temperatures exceeding Eagle XG®'s strain point. The inflection can be removed at higher laser powers (leftmost curve) and can induce a seamless transition from LMG, IRA or UVA absorption to glass fusion. Exemplary laser welding can include sweeping this zone along the interfacial boundaries to be bonded. Three criteria are described in the list shown in the lower right corner and in greater detail below, e.g., low melting film absorbs/melts at an incident wavelength, color center formation in the glass, and/or temperature induced absorption in the glass in some embodiments. The absorption of the film may be sufficient alone without effect of color center formation or even temperature absorption effect. It should be noted that the order of events identified in FIG. 3 should not limit the scope of the claims appended herewith or be indicative of relative importance to the other listed events.

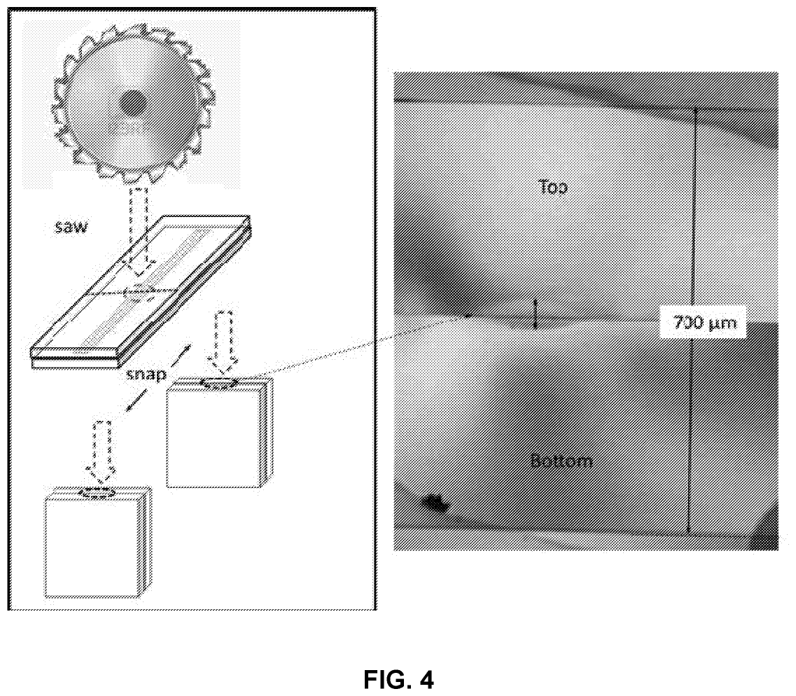

In some embodiments, the initiating event can be the UV laser absorption by the low melting glass (e.g., LMG or UVA) film. This can be based upon the larger absorbance of the thin film compared to Eagle XG® at 355 nm and the melting curves depicted in FIG. 3. Considering the experimental arrangement illustrated in the top left portion of FIG. 3, the laser was a Spectra Physics HIPPO 355 nm, generating 8-10 ns pulses at 30 kHz, up to 6.5 Watts of average power. The laser beam was focused to a 500 micron diameter beam waist, and the transmitted beam was monitored and sampled, yielding plots of the transmission percentage (% T) with time for different laser powers (5.0 W, 5.5 W, 6.0 W). These plots are shown in the lower left part of FIG. 3. The onset of melting of the UVA, IRA or LMG film can be readily observed in FIG. 3 at lower laser power (bottom and middle curves) as the knee like inflection followed by rapid absorption and heating of the glass substrate, due to high local glass temperatures, which exceed Eagle XG®'s strain point. The glass parts being welded may not be melted but are rather only softened so they become pliant when held in intimate contact with a modest applied force. This behavior can be similar to solid state diffusion bonding, particularly in the ability to form strong bonds at between 50-80% of the substrate's melting temperature. An optical cross sectional image of the solid-state bond's birefringence illustrates a distinct interface line between the two parts being welded (see, e.g., FIG. 4).

Some embodiments include welding with a 355-nm pulsed laser, producing a train of 1 ns pulses at 1 MHz, 2 MHz or 5 MHz repetition rates. When focusing the beam on the inorganic film into a spot between 0.02 mm and 0.15 mm diameter and welding with speeds ranging from 50 mm/s to 400 mm/s, defect-free bonding lines of approximately 60 μm to approximately 200 μm were produced. Required laser powers can range from approximately 1 W to approximately 10 W.

With reference to FIG. 4, an experimental arrangement is illustrated which was used to estimate physical extent of laser welding bonding zone. With continued reference to FIG. 4, two Eagle XG® slides were laser welded as previously described, mounted in a glass sandwich and cut with a diamond saw. This is illustrated in the left panel of FIG. 4. The resulting cross section was mounted in a polarimeter to measure the optical birefringence resulting from local stress regions. This is shown in the right panel of FIG. 4. The lighter regions in this right panel indicate more stress. As illustrated in the right panel of FIG. 4, a bonded region appeared having a physical extent on the order 50 μm. Further, there does not appear to be any base or substrate glass melting, however, the bond formed between the two glass substrates was very strong. For example, the image in the center of the birefringence image cross section depicts a solid-state bond region extending deep (50 μm) into the Eagle XG® substrate which illustrates high seal strength. Laser welding would include sweeping this zone along the interfacial boundaries to be bonded.

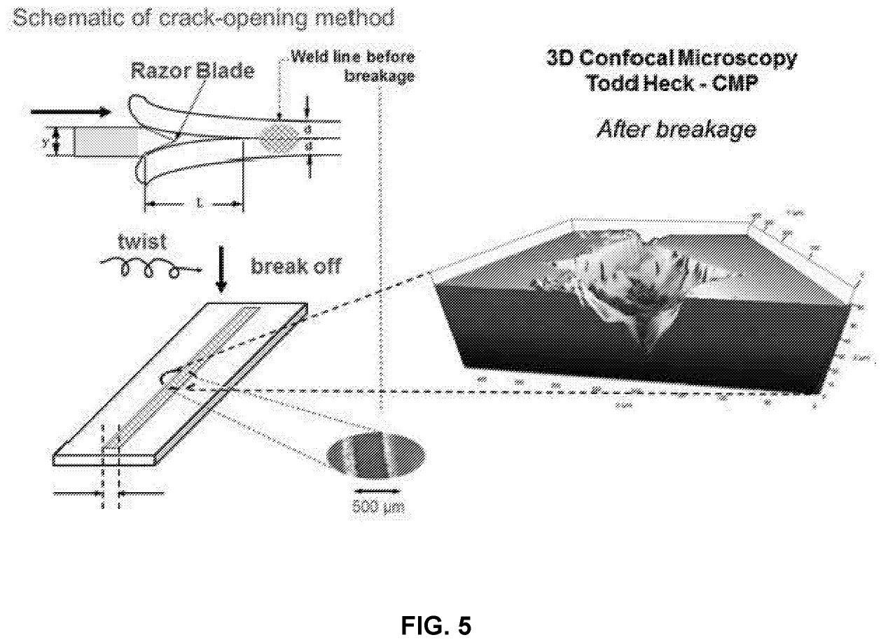

FIG. 5 is a microscopic image of fractured samples. With reference to FIG. 5, the illustrated three dimensional confocal microscopic images of fractured samples illustrate that the seal strength of embodiments of the present disclosure can be sufficiently strong such that failure occurs by ripping out the underlying substrate (e.g., Eagle XG® substrate) material as deep as 44 μm (i.e., a cohesive failure). No annealing was performed on the samples. FIG. 5 further illustrates a fractured sample of a non-annealed laser welded embodiment subjected to a razor blade crack opening technique. A series of three dimensional confocal measurements were made, and a representative example is shown on the right side of FIG. 5. One feature of these confocal images shows that the interfacial seal strength can be sufficiently strong so that failure occurs within the bulk of the substrate material, e.g., as deep as 44 μm away from the interface in this instance and in other experiments as deep as approximately 200 μm. In additional experiments, polarimetry measurements showed a residual stress occurring in the nascent laser weld (the same condition studied in FIG. 5) that was annealed at 600° C. for one hour, resulting in a tenacious bond exhibiting no measureable stress via polarimetry. Attempts at breaking such a bond resulted in breakage everywhere else except the seal line of the welded substrates.

As noted in FIG. 3, strong, hermetic, transparent bonds can be achieved using embodiments of the present disclosure by an exemplary low melting film or another film that absorbs/melts at an incident wavelength, color center formation in the film and glass, and temperature induced absorption in the film and glass. With regard to the first criterion, e.g., the low melting glass absorption event, laser illumination of the glass-LMG/UVA-glass structure with sufficiently high power per unit area can initiate absorption in the sputtered thin film LMG/UVA interface, inducing melting. This can be readily observed in the bottom curve of FIG. 3 in the lower left corner. The first downward slope of the bottom curve tracks the LMG/UVA melting process out to about 15 seconds, at which point another process occurs, this one being a glass-laser interaction (i.e., color center formation) in the respective substrate. The large curvature of this middle downward curve, after about 17 seconds would indicate a large absorption resulting from color centers forming in the glass. These color centers can generally be a function of the elemental impurity content in the substrate, e.g., As, Fe, Ga, K, Mn, Na, P, Sb, Ti, Zn, Sn to name a few. The more curvature in the transmission curve, the more color centers form. This is the second criterion noted in FIG. 3. The melting point of the LMG/UVA film can be, but is not limited to, about 450° C., but the interfacial temperature can likely be above 660° C. based upon observations of a laser illumination experiment with a surrogate aluminum-coated EXG glass substrate under similar laser welding conditions. In this experiment, the aluminum melted (melting temperature: 660° C.), and the surface temperature was measured with a calibrated thermal imaging camera (FLIR camera) to be about 250° C. using laser welding conditions.

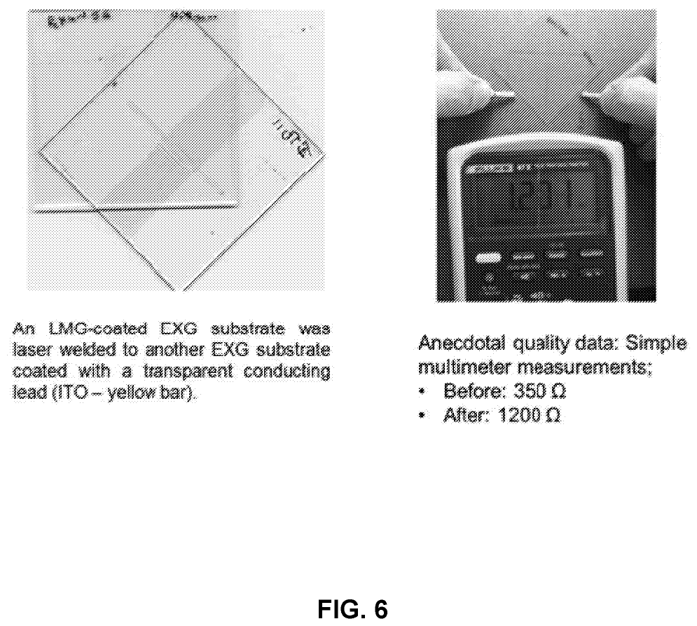

While the description heretofore has described laser welding of glass to glass substrates (of similar or different dimensions, geometries, and/or thicknesses), this should not limit the scope of the claims appended herewith as some embodiments are equally applicable to substrates or sheets of non-glass materials, such as, but not limited to ceramics, glass-ceramics, metals, and the like with, or without, an interfacial conductive film. For example, FIG. 6 is an illustration of an experiment assessing the extent of laser welding over ITO leads. With reference to FIG. 6, an LMG-coated Eagle XG® slide is illustrated laser welded to an ITO-coated Eagle XG® slide in the left panel of the figure. In this experiment, a 100 nm ITO film was deposited onto Eagle XG® substrates by reactive sputtering through a mask. Conditions were selected resulting in ITO films having a relatively high average sheet resistance of approximately 126Ω per square (Ω/sq), with a standard-deviation of 23 Ω/sq, reflecting that no thermal heating of the substrate was employed, before, during or after, the reactive sputtering deposition. The ITO film appears in FIG. 6 as a distinct yellowish or shaded strip, diagonally distributed in the photograph. Multimeter measurements of 350Ω were recorded over the distance indicated, prior to laser welding. An LMG-coated Eagle XG® slide was then laser welded to an ITO-coated Eagle XG® slide whereby it was discovered that the laser weld line was quite distinct, strong, transparent, and diagonally distributed but inverted. In the right panel of FIG. 6, post laser-weld measurement of the resistance across the ITO leads over the same distance used earlier was observed to increase the resistance from 350Ω to 1200Ω. The drop in conductivity was due to partial damage of the ITO film as the ITO film absorbed 355 nm radiation. To avoid damage of ITO film due to overheating, however, embodiments can change laser parameters so temperature at the interface does not transition from bare glass substrate to ITO film substrate or otherwise (e.g., variable peak power, variable repetition rate, variable average power, variable translation speed of the beam, electrode pattern, LMG film thickness, etc.).

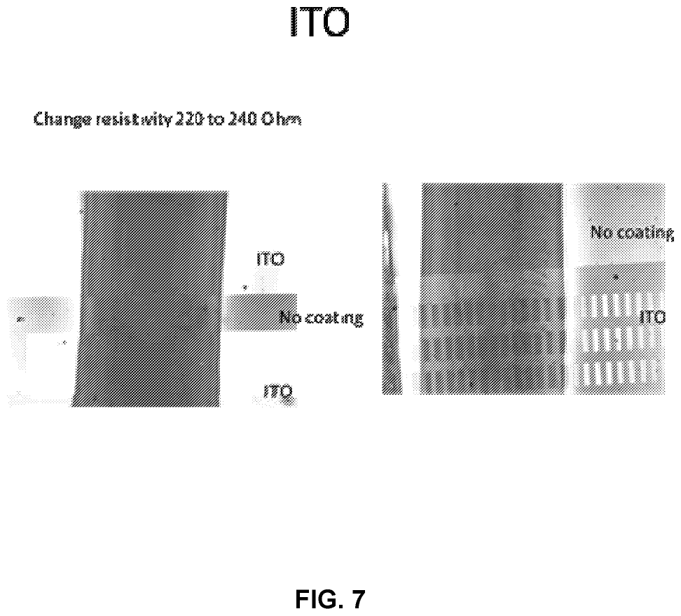

FIG. 7 provides additional photographs of laser seal lines formed over an ITO patterned film. With reference to the left panel of FIG. 7, another electrode type was obtained from a different source, again made from ITO and having a thickness of approximately 250 nm. The ITO film was continuous, over which seals were formed using methods described herein. The initial resistance, over an approximate 10 mm distance, was measured at 220 Ohms. Laser sealing was performed at constant speed and power when transitioning from the clear glass to the electrode area. After sealing was performed, a strong seal was observed over both clear glass and ITO regions, with the seal over ITO being slightly wider by approximately 10-15%. Such an increase in seal width may suggest that there is more heat generated in this region than in the clear area. Additional heat generation can also be caused by absorption of the electrode material by the laser radiation or by different thermal diffusivity properties of the film, and in any case, resistance was measured to increase approximately 10% to 240Ω which is insignificant. This can also indicate that when the temperature was raised relative to bare glass, the higher quality ITO and thicker film did not exhibit conductivity degradation. It should be noted that lowering the laser sealing power when it transitions from the clear glass to the electrode area can reduce extra heat generation and therefore decrease resistivity degradation in ITO. Experimental results also suggest that a single electrode split into an array of electrodes (having the same total width as the original electrode) at the seal location(s) can be optimal when using an electrode width between ½-½ of the laser beam width, and spacing between ½-⅓ of the beam diameter. Later experiments conducted with an increased sealing speed above 20 mm/s showed that resistance degradation was less <1-2% after sealing with a starting resistance of about 200Ω.

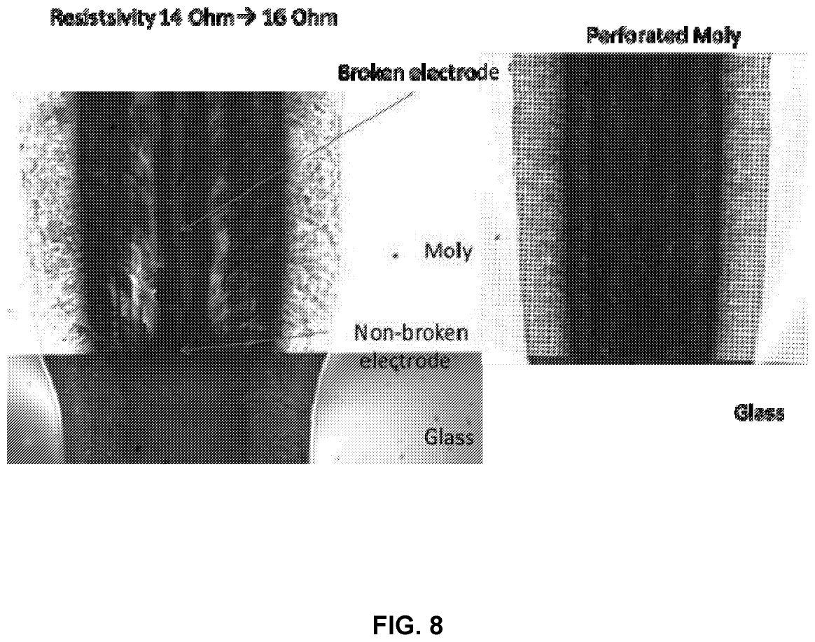

FIG. 8 is a series of photographs of additional laser seal lines formed over a patterned film. With reference to FIG. 8, similar experiments were performed with a non-transparent molybdenum metal electrode. FIG. 8 provides a series of photographs of continuous and patterned molybdenum interfacial film are shown over which laser seal lines were formed. In the left panels, a photograph of a continuous molybdenum film illustrates a more heterogeneous bond formation with cracked or broken molybdenum electrode portions. Even in this case, at constant laser sealing power, the uniform molybdenum electrode was not completely damaged. However, due to laser radiation absorption or reflection by the uniform electrode, the heating was substantially higher at the electrode area than in the clear glass region. This can be observed by the increased width area of the seal over the molybdenum region. It should be noted that one area that was undamaged was at the transition zone between the clear and uniform molybdenum areas thereby suggesting that power adjustment, laser power density, laser spot speed, or combination of all three factors during the sealing event can overcome any overheating effect for a uniform molybdenum electrode. In the right panel of FIG. 8, a photograph of a patterned or perforated molybdenum film illustrates a more homogeneous bond formation resulting in minimal perturbation to its conductivity, namely, 14Ω before welding to 16Ω after welding. The sealing over this perforated region exhibited much less heating and therefore presents an alternative to the power modulation method. It should also be noted that electrode metals should be carefully selected as it was discovered that sealing with metals having a low melting temperature (Al) are unlikely to survive the sealing conditions, in comparison to molybdenum (650° C. vs. 1200° C.) or other metals having a high melting temperature. Thus, the results suggest that a single electrode split into an array of electrodes (having the same total width as the original electrode) at the seal location can be optimal when using an electrode width between ½-⅓ of the laser beam width and spacing between ½-⅓ of the beam diameter. Thus, embodiments of the present disclosure are applicable to laser sealing of glass to glass, metal, glass-ceramic, ceramic and other substrates of equal or different dimensions, geometries and thicknesses.

Applications that may utilize some embodiments described herein having efficient formation of high bond-strength, transparent, glass-to-glass welds are numerous and include, but are not limited to, solid state lighting, display, and transparent vacuum insulated technologies. Laser welding of glass, in particular, can provide efficiencies and features such as a small heat affected zone (HAZ) that many traditional welding methods, such as e-beam, arc, plasma, or torch simply cannot provide. In some embodiments, laser glass welding can generally proceed without pre- or post-heating using infrared (IR) lasers for which many glasses are opaque or ultra-short pulse lasers (USPL) for which many glasses are transparent. In some embodiments, a judicious choice of glass substrate compositions and interfacially distributed IR absorbing frit can make hermetic glass “sandwich-type” laser sealed packages possible. In some embodiments, ultra-short pulsed lasers can be focused at either surface or interior points in an exemplary glass substrate and can induce absorption by non-linear processes such as multi-photon or avalanche ionization.

A low-power laser-welding process has been described that relies on an absorbing low melting glass interfacial film and can be attributed to diffusion welding, owing to its low temperature bond formation (as low as half the melting temperature), and requirement for contact and pressure conditions. Several effects were notable to laser welding glass sheets together with strong bond formation, e.g., an absorbing low melting glass film at the incident laser wavelength, laser induced color centers formed in the glass substrates, and thermal induced absorption in the substrate to effectively accelerating the temperature increase.

In some embodiments, however, many films highly absorbing at an incident wavelength (e.g., 355 nm) can be sufficient to induce high bond strength laser welds. Other films, for example, ZnO or SnO₂, are chemically different than some exemplary low melting glass compositions described herein but share the same laser welding capability at a relatively low light flux. Thus, it was discovered that the low melting character may not be necessary in some embodiments, in light of the melting temperature of ZnO (1975° C.) as compared with some low melting glass compositions (˜450° C.). It was discovered, however, that a unifying characteristic of these films was that they absorb radiation substantially at 355 nm: ZnO absorbance ˜45% (200 nm thick film), and low melting glass ˜15% (200 nm thick film). It was also determined that exemplary methods described herein could laser weld quartz, or pure fused silica substrates—i.e., substrates without color centers. Thus, it has been determined that color centers are not necessarily essential but may be helpful in some embodiments when absorption of an exemplary film is low (e.g., ˜Abs<20%).

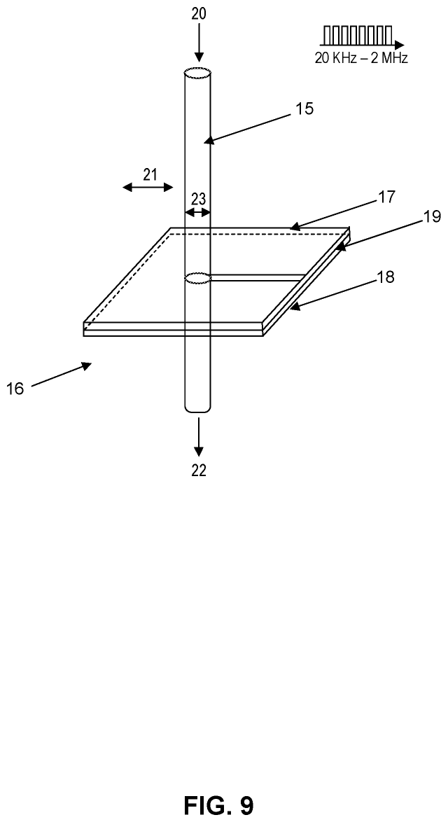

FIG. 9 is a simplified diagram of another method according to some embodiments. With reference to FIG. 9, a defocused laser beam 15 with a defined beam width 23 (or w) is incident, in the direction 20, on a sandwich-type structure 16 formed from contacting two sheets of glass 17, 18, with one sheet's interior interface coated with a thin absorbing film 19. While the beam is illustrated as cylindrical, such a depiction should not limit the scope of the claims appended herewith as the beam can be conical or another suitable geometry. The film material can be selected for its absorbance at the incident laser wavelength. The laser beam 15 can be translated at a predetermined speed, vₛ, and the time the translating laser beam can effectively illuminate a given spot and can be characterized by the dwell time, w/vₛ. In some embodiments, modest pressure can be applied during the welding or bonding event, ensuring a sustained contact between the clean surfaces, while any one or several parameters are adjusted to optimize the weld. Exemplary, non-limiting parameters include laser power, speed vₛ, repetition rate, and/or spot size w.

As noted above with reference to FIG. 3, it was discovered that optimum welding can be a function of three mechanisms, namely, absorption by an exemplary film and/or substrate of laser radiation and the heating effect based of this absorption process, increase of the film and substrate absorption due to the heating effects (band gap shift to the longer wavelength) which can be transient and depends upon the processing conditions, and defect or impurity absorption or color center absorption generated by UV radiation. Thermal distribution may be one aspect of this process.

While some embodiments have been described as utilizing low melting glass or inorganic films, the claims appended herewith should not be so limited as embodiments can use UV absorbing films, IRA films, and/or other inorganic films situated between two substrates. As noted above, in some embodiments, color center formation in an exemplary substrate glass is not necessary and is a function of the UV absorption of the film, e.g., less than about 20%. It follows that, in some embodiments, if the UV absorption of the film is greater than about 20%, alternative substrates such as quartz, low CTE substrates, and the like, can readily form welds. Furthermore, when high CTE substrates are used, these substrates can be readily welded with exemplary high repetition rate lasers (e.g., greater than about 300 kHz to about 5 MHz) and/or a low peak power. Furthermore, in embodiments where absorption of the film is a contributing factor, IR absorbing (visible transparent films) can be welded with the use of an exemplary IR laser system.

In some embodiments of the present disclosure, the glass sealing materials and resulting layers can be transparent and/or translucent, thin, impermeable, “green,” and configured to form hermetic seals at low temperatures and with sufficient seal strength to accommodate large differences in CTE between the sealing material and the adjacent substrates. In some embodiments, the sealing layers can be free of fillers and/or binders. The inorganic materials used to form the sealing layer(s) can be non-fit-based or powders formed from ground glasses in some embodiments (e.g., UVA, LMG, etc.). In some embodiments, the sealing layer material is a low T_{g} glass that has a substantial optical absorption cross-section at a predetermined wavelength which matches or substantially matches the operating wavelength of a laser used in the sealing process. In some embodiments, absorption at room temperature of a laser processing wavelength by the low T_{g} glass layer is at least 15%.

In some embodiments, suitable sealant materials include low T_{g} glasses and suitably reactive oxides of copper or tin. The glass sealing material can be formed from low T_{g} materials such as phosphate glasses, borate glasses, tellurite glasses and chalcogenide glasses. As defined herein, a low T_{g} glass material has a glass transition temperature of less than 400° C., e.g., less than 350, 300, 250 or 200° C. Exemplary borate and phosphate glasses include tin phosphates, tin fluorophosphates and tin fluoroborates. Sputtering targets can include such glass materials or, alternatively, precursors thereof. Exemplary copper and tin oxides are CuO and SnO, which can be formed from sputtering targets comprising pressed powders of these materials. Optionally, the glass sealing compositions can include one or more dopants, including but not limited to tungsten, cerium and niobium. Such dopants, if included, can affect, for example, the optical properties of the glass layer, and can be used to control the absorption by the glass layer of laser radiation. For instance, doping with ceria can increase the absorption by a low T_{g} glass barrier at laser processing wavelengths. Additional suitable sealant materials include laser absorbing low liquidus temperature (LLT) materials with a liquidus temperature less than or equal to about 1000° C., less than or equal to about 600° C., or less than or equal to about 400° C. In some embodiments, the composition of the inorganic film can be selected to lower the activation energy for inducing creep flow of the first substrate, the second substrate, or both the first and second substrates as described above.

Exemplary tin fluorophosphate glass compositions can be expressed in terms of the respective compositions of SnO, SnF₂ and P₂O₅ in a corresponding ternary phase diagram. Suitable UVA glass films can include SnO₂, ZnO, TiO₂, ITO, and other low melting glass compositions. Suitable tin fluorophosphates glasses include 20-100 mol % SnO, 0-50 mol % SnF₂ and 0-30 mol % P₂O₅. These tin fluorophosphates glass compositions can optionally include 0-10 mol % WO₃, 0-10 mol % CeO₂ and/or 0-5 mol % Nb₂O₅. For example, a composition of a doped tin fluorophosphate starting material suitable for forming a glass sealing layer comprises 35 to 50 mole percent SnO, 30 to 40 mole percent SnF₂, 15 to 25 mole percent P₂O₅, and 1.5 to 3 mole percent of a dopant oxide such as WO₃, CeO₂ and/or Nb₂O₅. A tin fluorophosphate glass composition according to one particular embodiment can be a niobium-doped tin oxide/tin fluorophosphate/phosphorus pentoxide glass comprising about 38.7 mol % SnO, 39.6 mol % SnF₂, 19.9 mol % P₂O₅ and 1.8 mol % Nb₂O₅. Sputtering targets that can be used to form such a glass layer may include, expressed in terms of atomic mole percent, 23.04% Sn, 15.36% F, 12.16% P, 48.38% 0 and 1.06% Nb.

A tin phosphate glass composition according to another embodiment comprises about 27% Sn, 13% P and 60% 0, which can be derived from a sputtering target comprising, in atomic mole percent, about 27% Sn, 13% P and 60% 0. As will be appreciated, the various glass compositions disclosed herein may refer to the composition of the deposited layer or to the composition of the source sputtering target. As with the tin fluorophosphates glass compositions, example tin fluoroborate glass compositions can be expressed in terms of the respective ternary phase diagram compositions of SnO, SnF₂ and B₂O₃. Suitable tin fluoroborate glass compositions include 20-100 mol % SnO, 0-50 mol % SnF₂ and 0-30 mol % B₂O₃. These tin fluoroborate glass compositions can optionally include 0-10 mol % WO₃, 0-10 mol % CeO₂ and/or 0-5 mol % Nb₂O₅. Additional aspects of suitable low T_{g} glass compositions and methods used to form glass sealing layers from these materials are disclosed in commonly-assigned U.S. Pat. No. 5,089,446 and U.S. patent application Ser. Nos. 11/207,691, 11/544,262, 11/820,855, 12/072,784, 12/362,063, 12/763,541, 12/879,578, and 13/841,391 the entire contents of which are incorporated by reference herein.

Exemplary substrates (glass or otherwise) can have any suitable dimensions. Substrates can have areal (length and width) dimensions that independently range from 1 cm to 5 m (e.g., 0.1, 1, 2, 3, 4 or 5 m or within any range having any two of these values as endpoints) and a thickness dimension that can range from about 0.5 mm to 2 mm (e.g., 0.5, 0.6, 0.7, 0.8, 0.9, 1.0, 1.2, 1.5 or 2 mm or within any range having any two of these values as endpoints). In some embodiments, a substrate thickness can range from about 0.05 mm to 0.5 mm (e.g., 0.05, 0.1, 0.2, 0.3, 0.4 or 0.5 mm or within any range having any two of these values as endpoints). In some embodiments, a glass substrate thickness can range from about 2 mm to 10 mm (e.g., 2, 3, 4, 5, 6, 7, 8, 9 or 10 mm or within any range having any two of these values as endpoints). A total thickness of an exemplary glass sealing layer can range from about 100 nm to 10 μm. In some embodiments, a thickness of the layer can be less than 10 μm, e.g., less than 10, 5, 2, 1, 0.5 or 0.2 μm. Exemplary glass sealing layer thicknesses include 0.1, 0.2, 0.5, 1, 2, 5 or 10 μm or within any range having any two of these values as endpoints. The width of the sealed region, which can be proportional to the laser spot size, can be about 0.05 to 2 mm, e.g., 0.05, 0.1, 0.2, 0.5, 1, 1.5 or 2 mm, or within any range having any two of these values as endpoints. A translation rate of the laser (i.e., sealing rate) can range from about 1 mm/sec to 1000 mm/sec, such as 1, 2, 5, 10, 20, 50, 100, 200, 400, or 1000 mm/sec. The laser spot size (diameter) can be about 0.02 to 1 mm, e.g., 0.02, 0.05, 0.1, 0.2, 0.5, 1, 1.5 or 2 mm, or within any range having any two of these values as endpoints.

Thus, it has been discovered that suitable laser welding glass substrate interfaces can occur in embodiments of the present disclosure when the local glass temperature exceeds its strain or annealing temperature (e.g., 669° C. and 772° C. respectively for EXG) within a spatial extent, e.g., the “welding volume”. This volume can be dependent upon the incident laser power, the composition of the UVA or LMG melt, and color center formation (as a result of impurities in the respective substrates). Once attained, the volume can be swept over the interfacial regions to result in a rapid and strong seal between two substrates (glass or otherwise). Sealing speeds in excess of 5-1000 mm/s can be attained. Exemplary laser welds can experience an abrupt transition to relatively cold ambient temperatures from the high temperatures associated with the melt volume as it is swept away over the substrate regions of interest. The integrity of the hermetic seal and its respective strength can be maintained by slow cooling (self-annealing) of the hot base glass color center (relaxation) regions and the thinness of the UVA or LMG or MR thin film region (typically ½-1 μm) thereby nullifying any impact of CTE mismatching between the two respective substrates (glass or otherwise).

In some embodiments, the choice of the sealing layer material and the processing conditions for forming a sealing layer over a glass substrate are sufficiently flexible that the substrate is not adversely affected by formation of the glass layer. Low melting temperature glasses can be used to seal or bond different types of substrates. Sealable and/or bondable substrates include glasses, glass-glass laminates, glass-polymer laminates, glass-ceramics or ceramics, including gallium nitride, quartz, silica, calcium fluoride, magnesium fluoride or sapphire substrates. Additional substrates can be, but are not limited to, metal substrates including tungsten, molybdenum, copper, or other types of suitable metal substrates. In some embodiments, one substrate can be a phosphor-containing glass plate, which can be used, for example, in the assembly of a light emitting device. A phosphor-containing glass plate, for example, comprising one or more of a metal sulfide, metal silicate, metal aluminate or other suitable phosphor, can be used as a wavelength-conversion plate in white LED lamps. White LED lamps typically include a blue LED chip that is formed using a group III nitride-based compound semiconductor for emitting blue light. White LED lamps can be used in lighting systems, or as backlights for liquid crystal displays, for example. The low melting temperature glasses and associate sealing method disclosed herein can be used to seal or encapsulate the LED chip.

Exemplary processes according to embodiments of the present disclosure can be made possible because of the base substrate (glass or otherwise) properties due to the ability of the substrate to form color centers with the prevailing laser illumination conditions and resulting temperature enhancement. In some embodiments, the color center formation can be reversible if transparent seals are desired. If the substrates have dissimilar thicknesses, then thermally conductive substrates can be employed in some embodiments to restore weld integrity.

Some embodiments can thus utilize low melting temperature materials to laser-weld glass or other material substrates together with a low laser pulse peak-power to minimize creation of shock waves and to ensure no micro cracks appear which could compromise the tensile fracture strength. Exemplary embodiments can also provide diffusion welding without melt puddle propagation allowing an adequate lower temperature sealing process. Due to the thinness of the film region, embodiments of the present disclosure can nullify any impact of CTE mismatching between the two respective substrates and can be utilized to provide welding of similarly or dissimilarly dimensioned substrates. Further, in some embodiments, no patterning of film is required for sealing as occurs in the case of frit or staining materials, and manufacturers therefore do not have to reveal their proprietary designs.

The present disclosure also teaches how low melting temperature materials can be used to laser weld glass packages together enabling long lived hermetic operation of passive and active devices sensitive to degradation by attack of oxygen and moisture. As noted above, embodiments described herein provide UVA, LMG or other seals that can be thermally activated after assembly of the bonding surfaces using laser absorption and can enjoy a higher manufacturing efficiency since the rate of sealing each working device can be determined by thermal activation and bond formation, rather than the rate one encapsulates a device by inline thin film deposition in a vacuum or inert gas assembly line. This can enable large sheet multiple device sealing with subsequent scoring into individual devices (singulation), and due to high mechanical integrity the yield from singulation can be high.

Some embodiments provide a laser sealing process, e.g., laser welding, diffusing welding, etc., that relies upon color center formation within the glass substrates due to extrinsic color centers, e.g., impurities or dopants, or intrinsic color centers inherent to the glass, at an incident laser wavelength, combined with exemplary laser absorbing films. Some non-limiting examples of films include SnO₂, ZnO, TiO₂, ITO, and low melting glass films which can be employed at the interface of the glass substrates. Welds using these materials can provide visible transmission with sufficient UV absorption to initiate steady state gentle diffusion welding. These materials can also provide transparent laser welds having localized sealing temperatures suitable for diffusion welding. Such diffusion welding results in low power and temperature laser welding of the respective glass substrates and can produce superior transparent welds with efficient and fast welding speeds. Exemplary laser welding processes according to embodiments of the present disclosure can also rely upon photo-induced absorption properties of glass beyond color center formation to include temperature induced absorption.

Hermetic encapsulation of a workpiece using the disclosed materials and methods can facilitate long-lived operation of devices otherwise sensitive to degradation by oxygen and/or moisture attack. Example workpieces, devices or applications include flexible, rigid or semi-rigid organic LEDs, OLED lighting, OLED televisions, photovoltaics, MEMs displays, electrochromic windows, fluorophores, alkali metal electrodes, transparent conducting oxides, quantum dots, etc.

As used herein, a hermetic layer is a layer which, for practical purposes, is considered substantially airtight and substantially impervious to moisture and/or oxygen. By way of example, the hermetic seal can be configured to limit the transpiration (diffusion) of oxygen to less than about 10⁻² cm³/m²/day (e.g., less than about 10⁻³ cm³/m²/day), and limit the transpiration (diffusion) of water to about 10⁻² g/m²/day (e.g., less than about 10⁻³, 10⁻⁴, 10⁻⁵ or 10⁻⁶ g/m²/day). In embodiments, the hermetic seal substantially inhibits air and water from contacting a protected workpiece.

In some embodiments, a method of bonding two substrates comprises forming a first glass layer on a sealing surface of a first substrate, forming a second glass layer on a sealing surface of a second substrate, placing at least a portion of the first glass layer in physical contact with at least a portion of the second glass layer, and heating the glass layers to locally melt the glass layers and the sealing surfaces to form a glass-to-glass weld between the first and second substrates. In each of the sealing architectures disclosed herein, sealing using a low melting temperature glass layer can be accomplished by the local heating, melting and then cooling of both the glass layer and the glass substrate material located proximate to the sealing interface.

Some embodiments combine the ease of forming hermetic seals associated with laser welding to also form hermetic packages of active OLED or other devices to enable their widespread fabrication. Such fabrication would require welding over interfacial conductive films. Unlike the methods disclosed herein, conventional methods of laser sealing can sever such interfacial conducting leads would sever them especially if the interface temperature gets too high or there is deleterious laser radiation interaction with the conducting lead material. Some embodiments, however, provide an enabling disclosure of device structures requiring electrical biasing for hermetic device operation using interfacial low melting temperature glass material film. Some embodiments may thus provide a successful laser-welding of glass sheets or other substrates having an interfacial conductive film without destruction thereto or loss in performance.

In some embodiments, a method of bonding a workpiece comprises forming an inorganic film over a surface of a first substrate, arranging a workpiece to be protected between the first substrate and a second substrate wherein the film is in contact with the second substrate, and bonding the workpiece between the first and second substrates by locally heating the film with laser radiation having a predetermined wavelength. The inorganic film, the first substrate, or the second substrate can be transmissive at approximately 420 nm to approximately 750 nm. In some embodiments, each of the inorganic film, first substrate and second substrate are transmissive at approximately 420 nm to approximately 750 nm. In some embodiments, absorption of the inorganic film is more than 10% at a predetermined laser wavelength. In some embodiments, the composition of the inorganic film can be, but is not limited to, SnO₂, ZnO, TiO₂, ITO, Zn, Ti, Ce, Pb, Fe, Va, Cr, Mn, Mg, Ge, SnF₂, ZnF₂ and combinations thereof. In some embodiments, the composition of the inorganic film can be selected to lower the activation energy for inducing creep flow of the first substrate, the second substrate, or both the first and second substrates. In some embodiments, the composition of the inorganic film can be a laser absorbing low liquidus temperature material with a liquidus temperature less than or equal to about 1000° C., less than or equal to about 600° C., or less than or equal to about 400° C. In further embodiments, the step of bonding can create a bond having an integrated bond strength greater than an integrated bond strength of a residual stress field in the first substrate, second substrate or both the first and second substrates. In some embodiments, such a bond will fail only by cohesive failure. In some embodiments, the composition of the inorganic film comprises 20-100 mol % SnO, 0-50 mol % SnF₂, and 0-30 mol % P₂O₅ or B₂O₃. In some embodiments, the inorganic film and the first and second substrates have a combined internal transmission of more than 80% at approximately 420 nm to approximately 750 nm. In some embodiments, the step of bonding further comprises bonding the workpiece between the first and second substrates as a function of the composition of impurities in the first or second substrates and as a function of the composition of the inorganic film though the local heating of the inorganic film with laser radiation having a predetermined wavelength. Exemplary impurities in the first or second substrates can be, but are not limited to, As, Fe, Ga, K, Mn, Na, P, Sb, Ti, Zn, Sn and combinations thereof. In some embodiments, the first and second substrates have different lateral dimensions, different CTEs, different thicknesses, or combinations thereof. In some embodiments, one of the first and second substrates can be glass or glass-ceramic. Of course, the other of the first and second substrates can be a glass-ceramic, ceramic or metal. In some embodiments, the method can also include the step of annealing the bonded workpiece. In other embodiments, the laser radiation comprises UV radiation at a predetermined wavelength between approximately 193 nm to approximately 420 nm, NIR radiation at a predetermined wavelength between approximately 780 nm to approximately 5000 nm, can include a pulse-width from 1 to 40 nanoseconds and a repetition rate of at least 1 kHz, and/or can be continuous wave. In some embodiments, a thickness of the inorganic film ranges from about 10 nm to 100 micrometers. In some embodiments, the first, second or first and second substrates can comprise an alkaline earth boro-aluminosilicate glass, thermally strengthened glass, chemically strengthened glass, boro-silicate glass, alkali-aluminosilicate glass, soda-lime glass, and combinations thereof. In some embodiments, the method can include the step of moving a laser spot formed by the laser radiation at a speed of approximately 1 mm/s to approximately 1000 mm/s to create a minimal heating zone. This speed, in some embodiments, does not exceed the product of a diameter of the laser spot and a repetition rate of the laser radiation. In some embodiments, the step of bonding can create a bond line having a width of approximately 50 μm to approximately 1000μm. In some embodiments, the inorganic film, first substrate, or second substrate can be optically transparent before and after the step of bonding in a range of greater than 80%, between 80% to 90%, greater than 85%, or greater than 90% at about 420 nm to about 750 nm. An exemplary workpiece can be, but is not limited to, a light emitting diode, an organic light emitting diode, a conductive lead, a semiconductor chip, an ITO lead, a patterned electrode, a continuous electrode, quantum dot materials, phosphor, and combinations thereof.

In some embodiments, a bonded device is provided comprising an inorganic film formed over a surface of a first substrate, and a device protected between the first substrate and a second substrate wherein the inorganic film is in contact with the second substrate. In such an embodiment, the device includes a bond formed between the first and second substrates as a function of the composition of impurities in the first or second substrates and as a function of the composition of the inorganic film though a local heating of the inorganic film with laser radiation having a predetermined wavelength. Further, the inorganic film, the first substrate, or the second substrate can be transmissive at approximately 420 nm to approximately 750 nm. In another embodiment, each of the inorganic film, first substrate and second substrate are transmissive at approximately 420 nm to approximately 750 nm. In some embodiments, absorption of the inorganic film is more than 10% at a predetermined laser wavelength. In some embodiments, the composition of the inorganic film can be, but is not limited to, SnO₂, ZnO, TiO₂, ITO, Zn, Ti, Ce, Pb, Fe, Va, Cr, Mn, Mg, Ge, SnF₂, ZnF₂ and combinations thereof. In some embodiments, the composition of the inorganic film can be selected to lower the activation energy for inducing creep flow of the first substrate, the second substrate, or both the first and second substrates. In some embodiments, the composition of the inorganic film can be a laser absorbing low liquidus temperature material with a liquidus temperature less than or equal to about 1000° C., less than or equal to about 600° C., or less than or equal to about 400° C. In some embodiments, the bond can have an integrated bond strength greater than an integrated bond strength of a residual stress field in the first substrate, second substrate or both the first and second substrates. In some embodiments, such a bond will fail only by cohesive failure. In some embodiments, the composition of the inorganic film comprises 20-100 mol % SnO, 0-50 mol % SnF₂, and 0-30 mol % P₂O₅ or B₂O₃. In some embodiments, the inorganic film and the first and second substrates have a combined internal transmission of more than 80% at approximately 420 nm to approximately 750 nm. Exemplary impurities in the first or second substrates can be, but are not limited to, As, Fe, Ga, K, Mn, Na, P, Sb, Ti, Zn, Sn and combinations thereof. In some embodiments, the first and second substrates have different lateral dimensions, different CTEs, different thicknesses, or combinations thereof. In some embodiments, one of the first and second substrates can be glass or glass-ceramic. Of course, the other of the first and second substrates can be a glass-ceramic, ceramic or metal. In some embodiments, a thickness of the inorganic film ranges from about 10 nm to 100 micrometers. In some embodiments, the first, second or first and second substrates can comprise an alkaline earth boro-alumino silicate glass, alkali-aluminosilicate glass, thermally strengthened glass, chemically strengthened glass, soda-lime glass, boro-silicate glass and combinations thereof. In some embodiments, the inorganic film, first substrate, or second substrate can be optically transparent before and after the step of bonding in a range of greater than 80%, between 80% to 90%, greater than 85%, or greater than 90% at about 420 nm to about 750 nm. An exemplary device can be, but is not limited to, a light emitting diode, an organic light emitting diode, a conductive lead, a semiconductor chip, an ITO lead, a patterned electrode, a continuous electrode, quantum dot materials, phosphor, and combinations thereof. In some embodiments, the bond can be hermetic with a closed loop or with seal lines crossing at angles greater than about 1 degree, can include spatially separated bond spots, and/or can be located at less than about 1000 μm from heat sensitive material of the bond. In some embodiments, birefringence around the bond can be patterned.

In some embodiments, a method of protecting a device is provided comprising forming an inorganic film layer over a first portion surface of a first substrate, arranging a device to be protected between the first substrate and a second substrate wherein the sealing layer is in contact with the second substrate, and locally heating the inorganic film layer and the first and second substrates with laser radiation to melt the sealing layer and the substrates to form a seal between the substrates. The first substrate can be comprised of glass or glass-ceramics, and the second substrate can be comprised of metal, glass-ceramics or ceramic. In some embodiments, the first and second substrates have different lateral dimensions, different CTEs, different thicknesses, or combinations thereof. In other embodiments, the device can be, but is not limited to, an ITO lead, a patterned electrode, and a continuous electrode. In some embodiments, the step of locally heating further comprises adjusting power of the laser radiation to reduce damage to the formed seal. An exemplary film can be, but is not limited to, a low T_{g} glass, which comprises 20-100 mol % SnO, 0-50 mol % SnF₂, and 0-30 mol % P₂O₅ or B₂O₃. In other embodiments, the composition of the inorganic film can be selected to lower the activation energy for inducing creep flow of the first substrate, the second substrate, or both the first and second substrates. In another embodiment, the composition of the inorganic film can be a laser absorbing low liquidus temperature material with a liquidus temperature less than or equal to about 1000° C., less than or equal to about 600° C., or less than or equal to about 400° C. In some embodiments, the step of bonding can create a bond having an integrated bond strength greater than an integrated bond strength of a residual stress field in the first substrate, second substrate or both the first and second substrates. In some embodiments, such a bond will fail only by cohesive failure.

Additional disclosure relevant to laser welding can be found in US 2015/0027168 to Dabich, II et al., entitled “Laser Welding Transparent Glass Sheets Using Low Melting Glass or Thin Absorbing Films”; WO2014/182776 to Logunov et. al, entitled “Laser Welding Transparent Glass Sheets Using Low Melting Glass or Thin Absorbing Films”, the disclosure of which is incorporated by reference in its entirety.

Display Modules with Laser Weld Seal and Modular Display

It has been discovered that laser welds may be used to create display modules that can be fit together to make a modular display. Unexpectedly, pixels in such a display may be evenly spaced within modules (intra-modular pitch), and across modules (inter-modular pitch). As a result, boundaries between modules are not visible to a viewer viewing the modular display at recommended viewing distances. For viewing purposes, such a modular display is indistinguishable from a similarly sized display not having modules. And, the modular display has significant manufacturing and reliability advantages.

A single module may also be used as a discrete display, for example for a watch, phone display, or tablet display. Such a module has an unexpectedly small bezel, which may allow for devices having very small bezels. A “bezel” is the region between the active area of a display and the edge of the display. Coupled with appropriate electrical connections such as through-glass vias, and appropriate packaging, a device may be made where the active area of the screen extends to within a pixel pitch of the edge of the entire device, and there is a laser weld for sealing at such an edge.

OLEDs and related hybrid inorganic OLED devices (ILEDs) typically utilize pixels having an active area substantially less than the area of the pixel. The remaining area of the pixel is the inactive area. For example, OLED “fill-factors” are approximately 50% of the area-ratios available to them; OLEDs in such cases are said to have fill-factors that are roughly 50%. This spacing is not perceived by viewers if they are sufficiently far away and the far-field diffraction of two Lambertian neighboring sources “blend into one.” This is why charts are used to recommend different TV viewing distances based on the display's pixel resolution (e.g., 4K, 1080P, 720P, etc.). For example, a recommended minimum viewing distance for a 4K 50″ TV is three feet and three inches.

In some embodiments, the inactive area can be used to create a large TV display assembled from sub-display modules. Laser welds described herein can be transparent, ultrathin, for example 40 to 200 μm in some embodiments, and have strong seal strength, for example 80 to 120 MPa in some embodiments. So, it is possible to fabricate hermetic glass packages suitable for OLED-like device operation. In contrast, frit based seals are opaque, thick (˜0.7-5.0 mm), have a relatively weak seal strength (˜9 MPa), and are simply too thick for sealing in the inter-gap zone for commercially desirable displays.

Pixels are powered by electrical connections. In some embodiments, the laser welds described herein may be made over electrically conductive leads that run to the edge of a substrate on which pixels are disposed. But, the relatively wide range of laser conditions usable to perform glass-to-glass laser welds is often much reduced when welding over electrically conductive leads, particularly with less refractory materials. So, in some embodiments, electrical connections are made through the back side of the module rather than the module's lateral edges. This configuration allows for a wider range of parameters usable to perform glass-to-glass laser welds, which can lead to more robust modular structural designs.

In some embodiments, modular sub-display panels are assembled into a monolithic TV display structure for long-lived hermetic performance, with much reduced mechanical stresses.

Large TV displays may be assembled by tiling smaller hermetic OLED-like modules in tight-packed geometries. One can theoretically make any size TV having an arbitrarily large emitting area using these modular components. The inactive area of OLED-like devices resulting from the fill-factor of such devices can be exploited by use of strong yet ultrathin laser weld lines. Laser welds are transparent, ultrathin (about 40-200 μm), and have very strong seal strength, particularly compared with frit. Placing laser welds so close to the periphery of the sub-display modules make tiling possible in a way that maintains the distance between the active area of adjacent pixels whether those pixels are within a module or across modules, thus appearing seamless to the viewer even across different modular components. Long-range seal-stress buildup in large monolithic substrates is avoided by distributing stress over much smaller tile-displays, unlike large frit seal OLED TV displays. Improved packaging strength is possible by adding additional spot welds to the perimeter seals or other non-continuous seals in between pixels. Optimum tiling and interconnection biasing may be facilitated by building 3D through-hole via arrays in the back of the sub-display modules.

As used herein, “welding” refers to a fusing of material between two contacting substrates. The exact details of the fusion, whether or not mediated with a thin film or a flux, are secondary to the general migration of substrate materials into one another. Welding may be accomplished at temperatures at or above the melting temperature of one or both substrates, or at a lower temperature. Lower temperature welding may optionally be accompanied by a specified compression. For example, lower temperature welding can fuse metal pieces by hammering, or compressing, especially after rendering soft or pasty by heat, and sometimes addition of fusible material. The term “diffusion welding” may be used to describe such lower temperature welding mechanisms, including viscous mechanisms, creep, diffusion, etc. The specific mechanism, and whether any mechanism is present at all, may be determined by the prevailing pressure and temperature. So, while the specific type of laser welding described above in the section “Laser Welding With Interfacial UV Absorbing Film” is a desirable type of laser welding, it is not the only type of “laser welding.” In some embodiments, it is desirable to weld with a thin (<1 μm) laser absorbing interfacial film. An apparent “inter-diffusion” film at the interface may be used to describe the spatial extent that substrate materials migrate into one another, whether or not a thin interfacial absorbing film was present to help absorb laser light, and whether or not “diffusion” is the migration mechanism.

Laser welding as used herein results in a direct bond between welded substrates. In this respect, laser welding is distinct from other sealing mechanisms such as frit seal, sealing with solder joints, brazing, etc., which form “indirect bonds.” Failure modes often reflect differences between direct bonds and indirect bonds. “Cohesive failure” occurs with “direct bonds.” Cohesive failure means that bond failure is away from the interface that existed between substrates prior to welding, because the interface seal is strong. “Adhesive failure” occurs with “indirect bonds” where bond failure is within the solder, or frit, material layer itself, or at the interface between the solder or frit and the substrate. It has been found that, in the context of laser welding as described herein, when compared to other types of welding, direct bonds are generally stronger than indirect bonds, sometimes as high as by an order of magnitude.

One difference between a frit and a “thin UV absorbing (UVA) interfacial film” is that the frit often needs CTE matching “fillers,” while a UVA film does not. This lack of a need for fillers roughly occurs for UVA films less than 1 μm when subject to laser conditions appropriate for creating a weld, as opposed to simply melting the film. Thicker film (>about 2 μm) generally do not work since laser-induced CTE-mis-match stress build-up is too large and results in failure. Typical frit layers are roughly 5-20 μm thick since they incorporate the CTE-matching fillers. Without being bound to any theories as to why some embodiments work, with a laser weld, CTE-mis-match at the thin-film and substrate interface may be effectively diluted away due to significant material migration during laser welding.

In some embodiments, a “weld” may hermetically seal a first substrate to a second substrate without any other layer being present between the first and second substrates after welding. For example, while there may have been a thin light absorptive layer present between the first substrate and the second substrate prior to the welding process, such a layer may be significantly diluted by migrating away from the interfacial region, and incorporating substrate material by counter-migration during the welding process as the absorptive layer absorbs laser energy. Such migration may involve, for example, diffusion of the material of such a layer into the first and second substrates. Depending upon where such an absorptive layer was initially present, residual absorptive layer may be present between the first and second substrate after welding in regions outside the region of the weld.

Some embodiments described herein have at least one of many advantages:
i. Ability to Tile: Theoretically possible to make any size TV having an arbitrarily large emitting area using modular components.
ii. Thin weld lines enable welding within the inactive area.
iii. Long-range seal-stress buildup in large monolithic substrates is avoided by distributing stress over tile-displays, unlike a large frit seal OLED TV display.
iv. Ultrathin TVs designs may be facilitated by use of 3D vias.
v. Quantum dot-based LEDs have no need for color filter stacks, or LCD structures.
vi. Laser welded glass-to-glass seals may have much smaller seal widths than frit seals, and form much stronger bonds.
vii. With use of electrical connections through vias, electrical leads to the substrate edge and welding over such leads may be avoided—this opens up the full range of laser conditions to maximize bond strength.
viii. Power efficiency better managed than passive matrix OLED devices since long electrical lead lengths may be avoided.
ix. Better reliability—any given TV display can “be repaired” by swapping out any poorly manufactured “module.”
x. Improved strength of the packaging having perimeter seal and spot welds or non-continuous seal between pixels area is possible.

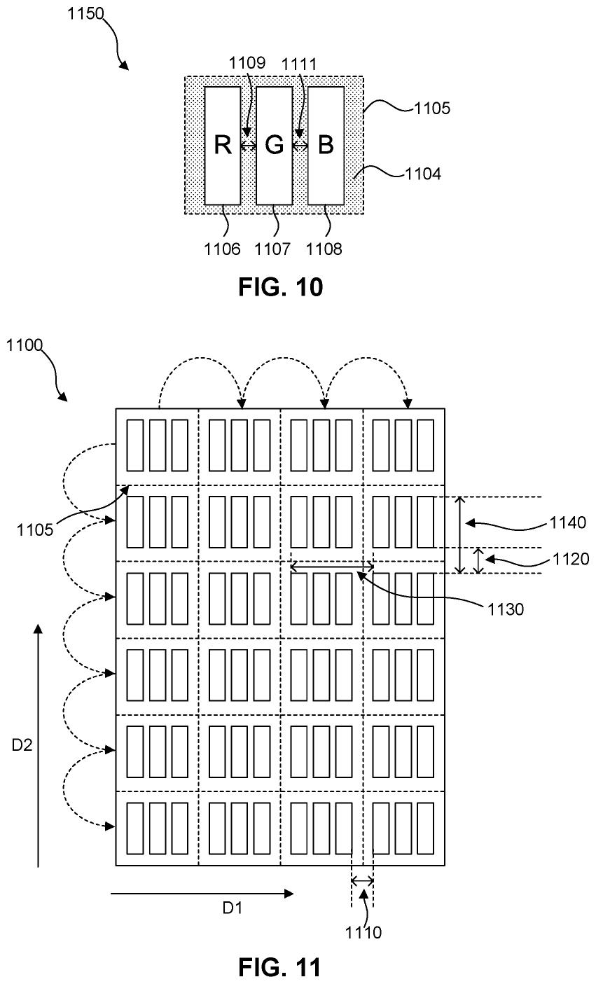

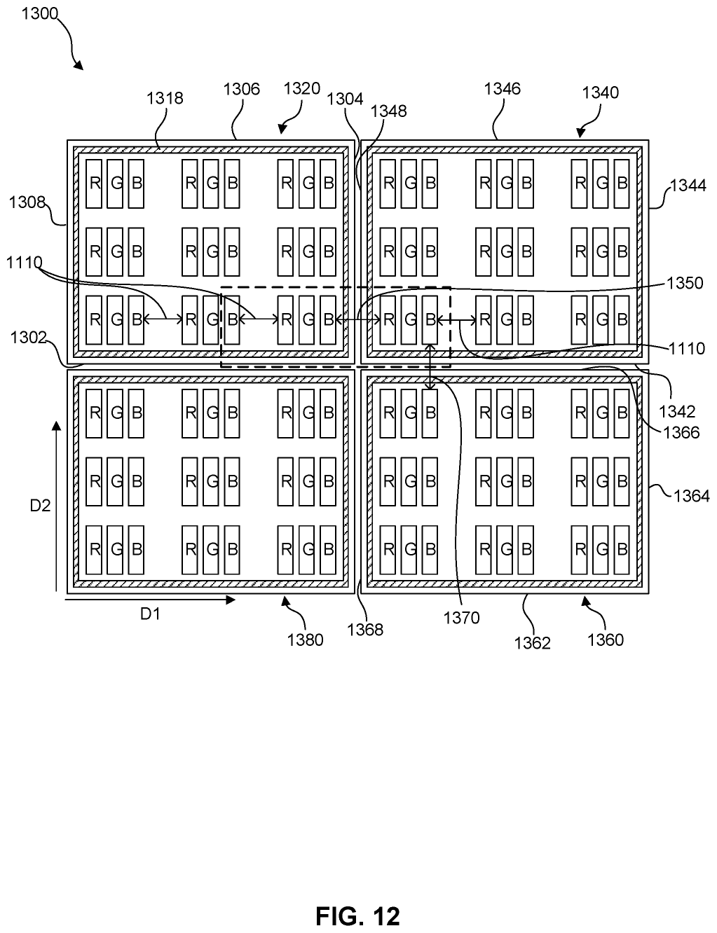

FIG. 10 illustrates a discrete exemplary unit cell 1150. FIG. 11 illustrates an exemplary pixel layout 1100 of a commercially available 55″ OLED TV. Pixel layout 1100 is formed by repeating pixel 1105 of FIG. 10 in the first direction D1 and in the second direction D2 perpendicular to first direction D1.

Pixel 1105 is a unit cell or the smallest repeating unit that forms a display. In some embodiments, for example, the light emitting devices are OLEDs (Organic Light Emitting Devices) or QD-LEDs (Quantum Dot Light Emitting Displays). FIG. 10 illustrates a pixel 1105 with a first intra-pixel gap 1109, defined as the distance between a first OLED 1106 and a second OLED 1107 in the first direction D1, and a second intra-pixel gap, 1111, defined as the distance between a second OLED 1107 and a third OLED 1108 in the first direction D1. The first intra-pixel gap 1109 and the second intra-pixel gap 1111 may have similar or different dimensions depending on the resolution and the type of display desired.

As illustrated in FIG. 10, each pixel 1105, has an active area and an inactive area 1104. The active area of a pixel refers to the light emitting area within the pixel. The active area of a pixel typically has an array of light emitting devices including OLEDs, QD-LEDs which are organic and inorganic hybrids, or any light emitting active area element array that has a “fill factor”, including inorganic LEDs (Light Emitting Devices). By way of example, OLEDs 1106, 1107 and 1108 in pixel 1105 would be considered as the active area. In some embodiments, the active areas of adjacent pixels are separated in the first direction D1 by a first intra-modular separation distance 1110 and in a second direction D2 by a second intra-modular separation distance 1120. In this context, “adjacent pixel” refers to the closest pixel in the same direction. The first intra-modular separation distance 1110 and the second intra-modular separation distance 1120 may be similar or different dimensions.

In some embodiments, the dimensions of the first intra-modular separation distance 1110 may be 2000 μm or less, 1750 μm or less, 1500 μm or less, 1250 μm or less, 1000 μm or less, 750 μm or less, 600 μm or less, 500 μm or less, 400 μm or less, 300 μm or less, 200 μm or less, 150 μm or less or within any range having any two of these values as endpoints. In some embodiments, the dimensions of the second intra-modular separation distance 1120 may be 2000 μm or less, 1750 μm or less, 1500 μm or less, 1250 μm or less, 1000 μm or less, 750 μm or less, 600 μm or less, 500 μm or less, 400 μm or less, 300 μm or less, 200 μm or less, 150 μm or less or within any range having any two of these values as endpoints.

In some embodiments, pixel 1105 has a first pitch 1130 in the first direction D1 and a second pitch 1140 in the second direction D2. First pitch 1130 can be defined as the distance between similar points on adjacent pixels in the first direction D1 and second pitch 1140 can be defined as the distance between similar points on adjacent pixels in the second direction D2. In some embodiments, first pitch 1130 in first direction D1 may be 50 μm or more, 100 μm or more, 200 μm or more, 300 μm or more, 400 μm or more, 500 μm or more, 600 μm or more, 700 μm or more, 800 μm or more, 900 μm or more, 1000 μm or more, 1100 μm or more, 1200 μm or more, 1300 μm or more, 1400 μm or more, 1500 μm or more or within any range having any two of these values as endpoints. In some embodiments, second pitch 1140 in second direction D2 may be 50 μm or more, 100 μm or more, 200 μm or more, 300 μm or more, 400 μm or more, 500 μm or more, 600 μm or more, 700 μm or more, 800 μm or more, 900 μm or more, 1000 μm or more, 1100 μm or more, 1200 μm or more, 1300 μm or more, 1400 μm or more, 1500 μm or more or within any range having any two of these values as endpoints.

In some embodiments, “fill factor” is defined as the ratio of the active area of a pixel to the total area of the pixel 1105. By way of example, FIG. 11, illustrates a pixel layout with roughly 50% fill factor.

Resolution of OLED displays can be quantified in terms of a well-defined pixel-density parameter expressed in terms of the number of pixels per inch, PPI. The inverse of the PPI is related to the “pitch,” or length and width of the repeating “unit-cell” often referred to as the “pixel”, assuming the pixels are square. Other pixel shapes are possible, such as rectangular pixels, diamond pixels, and even “pentile” pixels. Such pixels may also be incorporated into modular tiles with a repeating pattern. In such cases, the separation distance, dₛₑₚ is the distance between active areas of adjacent pixels.

A TV display “resolution” is also often described in terms of “4K”, “1080P”, “720P”, or “SD”. The display size is typically referred to in terms of the diagonal dimension. For example, a 10″ 4K TV refers to a rectangular display having a 10″ diagonal light emitting area with ˜4096 pixels distributed along the horizontal dimension, and ˜2160 pixels distributed along the vertical dimension. Table 1, shown below illustrates the recommended TV viewing distances for a variety of displays having different resolutions: 4K˜4096 pixels (tall)×2160 (wide) pixels, 1080P˜1980 (tall) pixels×1080 (wide) pixels, 720P˜1280 pixels (wide)×720 pixels (tall), and SD˜640 (tall) pixels×480 (wide) pixels. For example, one observes that the minimum distance a viewer should sit in front of a 4K 50″ TV is three feet and three inches.

| 16 × 9 | Resolution PPI | | | | | | | | | |
|---|---|---|---|---|---|---|---|---|---|---|
| Screen Size | >4K | | 4K | | 1080P | | 720P | | SD | |
| (Diagonal) | wide | tall | wide | tall | wide | tall | wide | tall | wide | tall |
| Units - | pixel | pixel | pixel | pixel | pixel | pixel | pixel | pixel | pixel | pixel |
| inches | >4096 | >2160 | 4096 | 2160 | 1983 | 1080 | 1280 | 720 | 640 | 480 |

| | | | | | |
|---|---|---|---|---|---|
| 10″ | <0′ 8″ | 0′ 8″-1′ 4″ | 1′ 4″-1′ 11″ | 1′ 11″-3′ 4″ | >3′ 4″ |
| 20″ | <1′ 4″ | 1′ 4″-2′ 7″ | 2′ 7″-3′ 11″ | 3′ 11″-6′ 7″ | >6′ 7″ |
| 30″ | <1′ 11″ | 1′ 11″-3′ 11″ | 3′ 11″-5′ 10″ | 5′ 10″-9′ 11″ | >9′ 11″ |
| 40″ | <2′ 7″ | 2′ 7″-5′ 2″ | 5′ 2″-7′ 10″ | 7′ 10″-13′ 3″ | >13′ 3″ |
| 50″ | <3′ 3″ | 3′ 3″-6′ 6″ | 6′ 6″-9′ 9″ | 9′ 9″-16′ 7″ | >16′ 7″ |
| 60″ | <3′ 11″ | 3′ 11″-7′ 10″ | 7′ 10″-11′ 8″ | 11′ 8″-19′ 10″ | >19′ 10″ |
| 70″ | <4′ 7″ | 4′ 7″-9′ 1″ | 9′ 1″-13′ 8″ | 13′ 8″-23′ 2″ | >23′ 2″ |
| 80″ | <5′ 2″ | 5′ 2″-10′ 5″ | 10′ 5″-15′ 7″ | 15′ 7″-26′ 6″ | >26′ 6″ |
| 90″ | <5′ 10″ | 5′ 10″-11′ 8″ | 11′ 8″-17′ 7″ | 17′ 7″-29′ 10″ | >29′ 10″ |
| 100″ | <6′ 6″ | 6′ 6″-13′ 0″ | 13′ 0″-19′ 6″ | 19′ 6″-33′ 1″ | >33′ 1″ |
| 110″ | <7′ 2″ | 7′ 2″-14′ 4″ | 14′ 4″-21′ 5″ | 21′ 5″-36′ 5″ | >36′ 5″ |
| 120″ | <7′ 10″ | 7′ 10″-15′ 7″ | 15′ 7″-23′ 5″ | 23′ 5″-39′ 9″ | <39′ 9″ |

Recommended viewing distance (inches)

Table 1. A range of recommended viewing distances for a variety of display sizes having different resolutions.

Display resolution can also be defined in terms of pixel density or pixels per inch, PPI. The expression below can be used to derive the pixel density, PPI for a display of a certain size and resolution.

$$PPI ≡ \frac{{d}_{p}}{{d}_{i}} = \frac{\sqrt{{w}_{p}^{2} + {h}_{p}^{2}}}{{d}_{i}} \qquad ( Eq . 1 )$$

In Eq. 1, wₚ is the number of pixels along the width of the display, hₚ is the number of pixels along the height of the pixel, dₚ is the number of pixels along the diagonal of the display and dᵢ is the diagonal length of the display in inches. For example, for a 4K 21.5″ display screen, the PPI≈219. The calculation is as shown below:

$$PPI = \frac{\sqrt{{4096}^{2} + {2304}^{2}}}{{21.5}^{″}} \approx \frac{219 pixel}{inch} \qquad ( Eq . 2 )$$

Similarly, we convert the lower bound viewing distance entries in Table 1 into Table 2 below tabulating the associated PPI values using equation 1. The inverse relationship between PPI and TV size in equation 1 can be seen in Table 2 by tracking the drop in magnitude down any given column. The PPI magnitude though, scales as the square-root of TV size-squared, which can be roughly tracked by scanning along a row from left-high resolution (>4K), to right-low resolution (SD). The PPI appears to simply scale with the size of the display screen.

TABLE 2
Pixel density (PPI) for a variety of display sizes having different resolutions.

| 16 × 9 | | | | | | | | | | |
|---|---|---|---|---|---|---|---|---|---|---|
| Screen | Resolution PPI | | | | | | | | | |
| Size | >4K | | 4K | | 1080P | | 720P | | SD | |
| (Diagonal) | wide | tall | wide | tall | wide | tall | wide | tall | wide | tall |
| Units - | pixel | pixel | pixel | pixel | pixel | pixel | pixel | pixel | pixel | pixel |
| inches | >4096 | >2160 | 4096 | 2160 | 1983 | 1080 | 1280 | 720 | 640 | 480 |

| | | | | | |
|---|---|---|---|---|---|
| 10″ | >463 | 463 | 226 | 147 | 80 |
| 20″ | >232 | 232 | 113 | 73 | 40 |
| 30″ | >154 | 154 | 75 | 49 | 27 |
| 40″ | >116 | 116 | 56 | 37 | 20 |
| 50″ | >93 | 93 | 45 | 29 | 16 |
| 60″ | >77 | 77 | 38 | 24 | 13 |
| 70″ | >66 | 66 | 32 | 21 | 11 |
| 80″ | >58 | 58 | 28 | 18 | 10 |
| 90″ | >51 | 51 | 25 | 16 | 9 |
| 100″ | >46 | 46 | 23 | 15 | 8 |
| 110″ | >42 | 42 | 21 | 13 | 7 |
| 120″ | >39 | 39 | 19 | 12 | 7 |

Pixels per inch (PPI)

Separation distance is related to PPI & fill-factor. And, there is a PPI such that a display screen is packed with so many pixels such that the individual cells are indiscernible with your naked eye. A 20/20 vision criteria is defined where the smallest resolvable detail for an average eye is around one “arcminute”, which is an accepted value among academics for the resolution limit of a typical human retina. We define the specific PPI threshold that satisfies the retinal display condition as PPI_{20/20}. The smallest resolvable detail for two adjacent pixels separated a distance s from a viewing distance d is given by

$$tan ( \frac{a}{2} ) = \frac{s}{2 \cdot d} \approx 1.45444 \cdot {10}^{- 4} \qquad Eq . 3$$

where the viewing angle, a/2, is set to the 20/20 resolution limit of one arc minute, 1°/60. Recognizing that s is simply the pixel pitch, or “unit cell length”, we can define the PPI_{20/20} as

$${PPI}_{20 / 20} ≡ \frac{1}{s} \approx \frac{3437.749}{viewing distance} \approx \frac{3438}{d} \qquad Eq . 4$$

We formally relate the active emitter size to the fill-factor and PPI to ultimately determine the relationship between separation distance and viewing distance at the resolution limit of a typical human retina. Using the definitions in FIG. 1, we have

$$Active Emitter Size = Unit Cell Length \cdot Fill Factor = \frac{Fill Factor}{PPI} \qquad Eq . 5$$

We then relate the separation distance dₛₑₚ to PPI and fill-factor simply as

dₛₑₚ=Unit Cell Length−Active Emitter Size Eq. 6

From which we establish the relationship,

$${d}_{sep} = Unit Cell Length - Active Emitter Size = \frac{1}{PPI} - \frac{Fill Factor}{PPI} = \frac{( 1 - Fill Factor )}{PPI} \qquad Eq . 7$$

Or more simply as,

$$Separation Distance , {d}_{sep} = \frac{( 1 - Fill Factor )}{PPI} \qquad Eq . 8$$

But we will only consider those pixel displays whose pixel density, PPI, satisfy the “retinal display” pixel density, PPI_{20/20}, established in Equation 4. Thus, the previous relationship, Eq. 8, becomes the following after substituting PPI for PPI_{20/20}

$$Separation Distance , {d}_{sep} = \frac{( 1 - Fill Factor )}{{PPI}_{20 / 20}} \qquad Eq . 9$$

And finally, inserting the expression from Eq. 4, we have the relationship,

$$Separation Distance , {d}_{sep} \approx \frac{d \cdot ( 1 - Fill Factor )}{3438} \qquad Eq . 10$$

We can now relate the spacing between active light emitting elements required of a display satisfying the retinal display condition for any given viewing distance using Eq. 10. Specifically, we convert the lower-bound viewing distance entries in Table 1 into Table 3 below containing the separation distance dₛₑₚ values using Eq. 10.

As shown in Table 3, the separation distance for a similar TV display screen size decreases from the right of Table 3 (SD) to the left (high resolution, >4K). The separation distance for different screen sizes almost linearly scales from the top of the Table 3 to the bottom, through various specific display resolutions.

TABLE 3
Separation distance for a variety of display sizes having different resolutions.

| 16 × 9 | | | | | | | | | | |
|---|---|---|---|---|---|---|---|---|---|---|
| Screen | Resolution | | | | | | | | | |
| Size | >4K | | 4K | | 1080P | | 720P | | SD | |
| Lower | wide | tall | wide | tall | wide | tall | wide | tall | wide | tall |
| Bound | pixel | pixel | pixel | pixel | pixel | pixel | pixel | pixel | pixel | pixel |
| View- | >4096 | >2160 | 4096 | 2160 | 1983 | 1080 | 1280 | 720 | 640 | 480 |

| | | | | | |
|---|---|---|---|---|---|
| 10″ | <30 | 30 | 59 | 85 | 148 |
| 20″ | <59 | 59 | 114 | 174 | 292 |
| 30″ | <86 | 86 | 174 | 258 | 440 |
| 40″ | <115 | 115 | 229 | 347 | 587 |
| 50″ | <144 | 144 | 288 | 432 | 735 |
| 60″ | <174 | 174 | 347 | 517 | 879 |
| 70″ | <203 | 203 | 402 | 606 | 1027 |
| 80″ | <229 | 229 | 462 | 691 | 1175 |
| 90″ | <258 | 258 | 517 | 779 | 1322 |
| 100″ | <289 | 289 | 576 | 864 | 1466 |
| 110″ | <318 | 318 | 635 | 950 | 1614 |
| 120″ | <347 | 347 | 691 | 1038 | 1762 |

Active Area “Separation-Distance” (micron)

In some embodiments, the first and second intra-modular separation distances are the same. Desirable ranges for intra-modular separation distances in both the first and second directions include not more than 2000 μm, not more than 1500 μm, not more than 1250 μm, not more than 1000 μm, not more than 750 μm, not more than 500 μm, and not more than 300 μm. It is desirable that, along the second and fourth linear edges, the distance between the periphery and the active area of the array of pixels in the first direction is not more than half the intra-modular separation distance in the first direction, and that, along the first and third linear edges, the distance between the periphery and the active area of the array of pixels in the second direction is not more than half the intra-modular separation distance in the first direction. So, desirable ranges for the distance between the periphery and the active area of the array of pixels in the first direction and the second direction include not more than 1000 μm, not more than 750 μm, not more than 625 μm, not more than 500 μm, not more than 375 μm, not more than 250 μm, and not more than 150 μm.

An intra-modular separation distance less than 2000 μm (for example, 1600 to 2000 μm), is desirable because it correlates roughly with a 120 inch SD resolution screen. An intra-modular separation distance less than 750 μm (for example, 600 to 750 μm), is desirable because it correlates roughly with a 120 inch 1080P resolution screen, which may account for a large portion of the home market for large display screens. An intra-modular separation distance less than 500 μm (for example, 300 to 500 μm), is desirable because it correlates roughly with a 120 inch 4K resolution screen, which may account for almost all of the remaining home market for large display screens. As can be seen from the table, many other intra-modular separation distances are desirable. In addition, laser welds provide superior seal strength and hermetic sealing properties to other types of seals such as frit seals and solder seals, particularly for smaller seal widths. For some ranges, such as an intra-modular separation distance less than 1000 μm, laser welds may be the only usable type of seal. And, even for larger intra-modular separation distances described herein, laser welds may provide far superior seals in terms of superior seal strength and hermetic sealing properties.

In some embodiments, the array of light emitting devices may include, not limiting to, a red OLED, a green OLED, a blue OLED, a white OLED, a red QD-LED, a green QD-LED, a blue QD-LED, a white QD-LED, LEDs, and combinations thereof. For example, a full-color display may include a grouping of red, green and blue OLED but a monochromatic display may include a single color OLED.

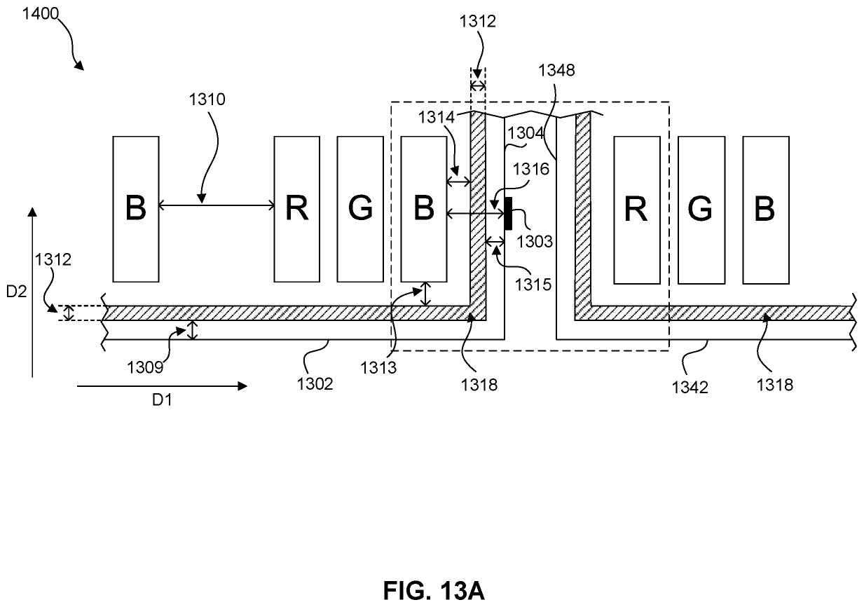

FIG. 12 illustrates a monolithic display 1300. The monolithic display 1300 may be made by assembling an array of modules in the first direction D1 and second direction D2. A first module 1320 has a first linear edge 1302 and a third linear edge 1306 in the first direction D1 and a second linear edge 1304 and a fourth linear edge 1308 in the second direction D2, perpendicular to the first direction D1. The modules are arranged such that the first module 1320 is joined to the second module 1340 along the second linear edge 1304 of the first module 1320 and the fourth linear edge of the second module 1340. In this context, “joined” may or may not refer to physically joined to each other in the sense of sealing, or welding as one. For example, modules may be connected to a common back plane. In the first direction D1, the active area of a pixel closest to the periphery along the second linear edge 1304 in the first module 1320 and the active area of an adjacent pixel closest to the periphery along the fourth linear edge 1348 in the second module 1340 are separated by a first inter-modular separation distance 1350. Similarly, in the second direction D2, the active area of a pixel closest to the periphery along the first linear edge 1342 in the second module 1340 and the active area of an adjacent pixel closest to the periphery along the third linear edge 1366 in the third module 1360 are separated by a second inter-modular separation distance 1370. The first inter-modular separation distance 1350 and the second inter-modular distance 1370 are not more than 5% different, not more than 10% different, not more than 15% different, not more than 20% different, not more than 25% different, not more than 30% different, not more than 35% different, not more than 40% different, or within any range having any two of these values as endpoints, than the first intra-modular separation distance 1110 in the first module 1320 and the second module 1340. It should be noted that the first intra-modular separation distance 1110, the second intra-modular separation distance 1120, the first inter-modular separation distance 1350 and the second inter-modular separation distance 1370 are exemplary and are primarily defined by the direction D1 or D2 and not by the module being discussed.

In some embodiments, the modules may be rectangular. “Rectangular modules” include square modules. “Rectangular modules” may or may not include small deviations from a perfect rectangle that occur in the area between the array of light emitting devices and the periphery. Such deviations might include a notch, small protrusion, beveled corner, or slight curve. For example, such deviations might be useful for ensuring that different modules having rectangular shapes are oriented properly (not rotated) when joined, such that the pixels and electrical connections are in their expected locations. Proper orientation can be ensured by introducing small shape deviations that only match up when the modules are properly oriented.

In some embodiments, where the module is a rectangle, each length of a rectangle may be 10 cm or less, 30 cm or less, 50 cm or less, 70 cm or less, 90 cm or less, 110 cm or less, 130 cm or less, 150 cm or less, 170 cm or less, 200 cm or less, 320 cm or less or within any range having any two of these values as endpoints.

In some embodiments, first module 1320 has a periphery along the first linear edge 1302 and the third linear edge 1306 in the first direction D1 and along the second linear edge 1304 and the fourth linear edge 1308, in the second direction D2 perpendicular to the first direction D1. First module 1320 may have a portion of the periphery 1303 along the second linear edge 1304 in the second direction D2.

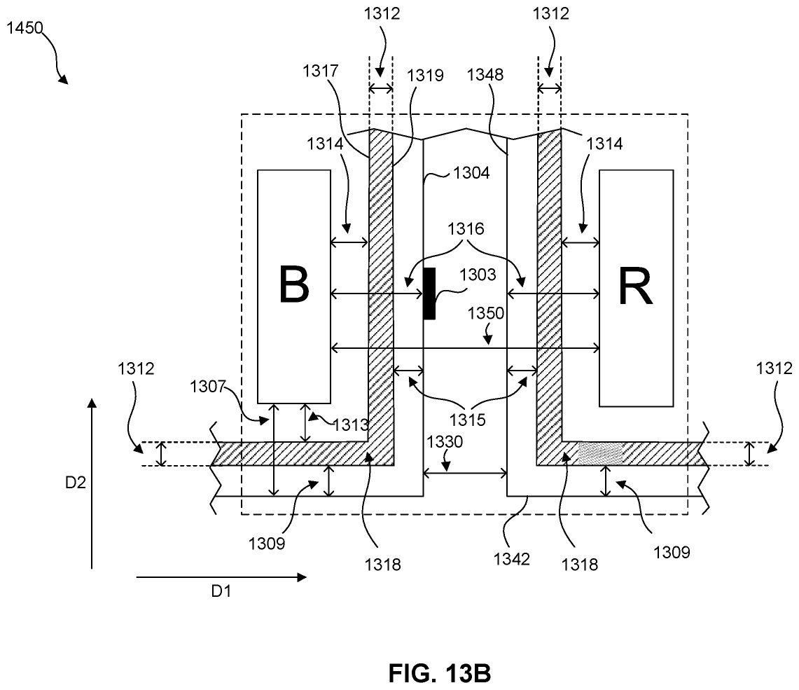

FIG. 13A illustrates a laser weld 1318 disposed between the array of light emitting devices and the periphery of the module 1320, along all the edges in both directions D1 and D2. The laser weld 1318 has a weld-width 1312 (WW) in the first direction D1. The laser weld 1318 may have a uniform weld-width 1312 along all the edges in both directions D1 and D2, but some variation may be acceptable. The laser weld 1318 has an inner edge 1317 and an outer edge 1319. The “width” of laser weld is the distance measured perpendicular to the length. The laser weld generally runs parallel to the periphery, such that the “width” of the weld is perpendicular to the periphery of the module. But, deviations from these criteria are permissible, for example at corners, or where a module is not being joined to another module at the outer edge of the display. In some embodiments, the weld-width 1312 of the laser weld 1318 may be 500 μm or less, 300 μm or less, 200 μm or less, 180 μm or less, 160 μm or less, 140 μm or less, 120 μm or less, 100 μm or less, 80 μm or less, 60 μm or less, 40 μm or less, 30 μm or less or within any range having any two of these values as endpoints.

FIG. 13B illustrates the laser weld 1318 having an inner edge 1317, defined as the edge of the laser weld closest to the active area of the pixel in the first direction D1 and the second direction D2, and an outer edge 1319, defined as the edge of the laser weld closest to the periphery of the first module 1320, in the first direction D1 and the second direction D2. Other dimensions illustrated in FIG. 13B include:
a. In the first direction D1:
   i. a first active area-to-weld distance 1314 (AW₁), defined as the distance between the inner edge 1317 of the laser weld 1318 and the active area of the pixel closest to the inner edge 1317.
   ii. a first weld-to-periphery distance 1315 (WP₁), defined as the distance between the outer edge 1319 of the laser weld 1318 and the portion of the periphery of first module 1320 closest to the outer edge 1319, along the second linear edge 1304.
   iii. a first active area-to-periphery distance 1316 (AP₁), defined as the distance between the active area of the pixel closest to the periphery and the periphery itself of the first module 1320, along the second linear edge 1304. In other words, the first active area-to-periphery distance 1316 can also be mathematically defined as follows:

AP₁=(AW₁+WW+W₁);
iv. a first inter-modular separation distance 1350, defined as the distance between two similar points from the active area of a pixel closest to the periphery of the first module 1320, to the active area of the adjacent pixel, parallel to the first direction D1 in the second module 1340.
v. a first inter-modular gap 1330 along the first direction D1, separating the first module 1320 and the second module 1340.
b. In the second direction D2:
   i. a second active area-to-weld distance 1313 (AW₂), defined as the distance between the inner edge 1317 of the laser weld 1318 and the active area of the pixel closest to the inner edge 1317.
   ii. a second weld-to-periphery distance 1315 (WP₂), defined as the distance between the outer edge 1319 of the laser weld 1318 and the portion of the periphery of first module 1320 closest to the outer edge 1319, along the first linear edge 1304.
   iii. a second active area-to-periphery distance 1307 (AP₂), defined as the distance between the active area of the pixel closest to the periphery and the periphery itself of the first module 1320, along the first linear edge 1302. In other words, the second active area-to-periphery distance 307 can also be mathematically defined as follows:

AP₂=(AW₂+WW+WP₂);

In some embodiments, the first active area-to-weld distance 1314 (AW₁) may be at least 50% of the weld-width, at least 60% of the weld-width, at least 70% of the weld-width, at least 80% of the weld-width, at least 90% of the weld-width, at least 100% of the weld-width, at least 150% of the weld-width, at least 200% of the weld-width, at least 250% of the weld-width or within any range having any two of these values as endpoints. In some embodiments, the second active area-to-weld distance 1313 (AW₂) may be at least 50% of the weld-width, at least 60% of the weld-width, at least 70% of the weld-width, at least 80% of the weld-width, at least 90% of the weld-width, at least 100% of the weld-width, at least 150% of the weld-width, at least 200% of the weld-width, at least 250% of the weld-width or within any range having any two of these values as endpoints.

In some embodiments, the first weld-to-periphery distance 1315 (WP₁), may be 0 μm or more, 1 μm or more, 5 μm or more, 10 μm or more, 15 μm or more, 20 μm or more, 25 μm or more, 30 μm or more, 35 μm or more, 40 μm or more, 45 μm or more, 50 μm or more, 70 μm or more, 90 μm or more, 100 μm or more, 200 μm or more or within any range having any two of these values as endpoints. In some embodiments, the second weld-to-periphery distance 1315 (WP₂), may be 0 μm or more, 1 μm or more, 5 μm or more, 10 μm or more, 15 μm or more, 20 μm or more, 25 μm or more, 30 μm or more, 35 μm or more, 40 μm or more, 45 μm or more, 50 μm or more, 70 μm or more, 90 μm or more, 100 μm or more, 200 μm or more or within any range having any two of these values as endpoints. In some embodiments, using appropriate welds and cutting techniques, a cut that defines the periphery may touch a weld, in which case the weld-to-periphery distance may be zero.

In some embodiments, the entire width of the laser weld is within 500 μm or less of the periphery. As used herein, “the entire width of the laser weld” refers to weld-width 1312 at a specific part of the periphery being considered. The entire width of the laser weld, can be about 60 μm to 2000 μm, e.g., 60 μm, 100 μm, 200 μm, 500 μm, 1000 μm, 1500 μm or 2000 μm, or within any range having any two of these values as endpoints.

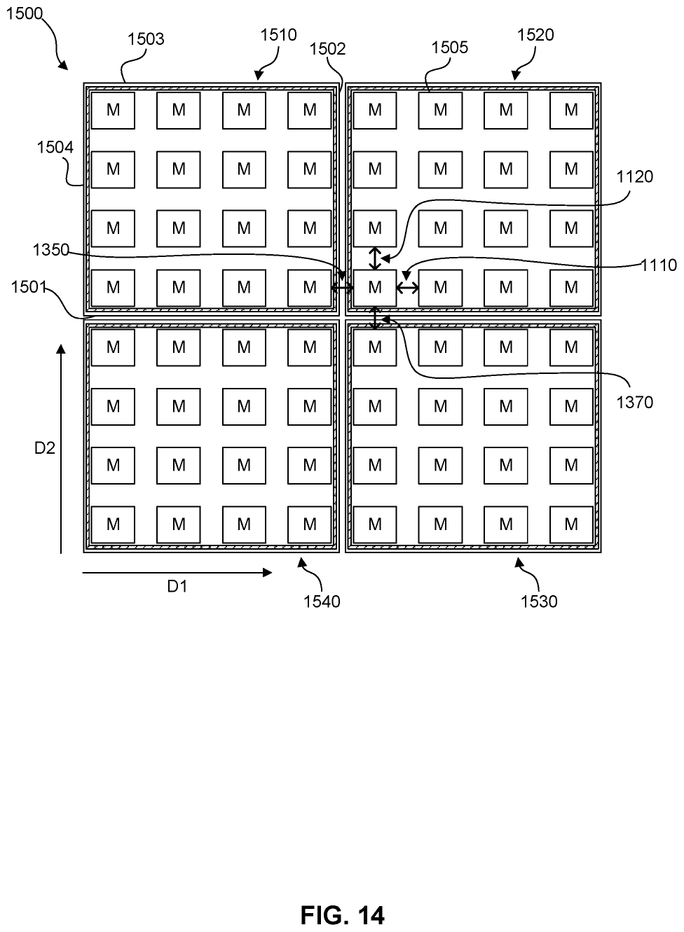

FIG. 14 illustrates an exemplary monochromatic display 1500 wherein the monochromatic display 1500 consists of a 2×2 array of rectangular modules joined together. The first monochromatic module 1510 includes a single-color light emitting device 1505 repeating in the first direction D1 and the second direction D2 perpendicular to the first direction D1.

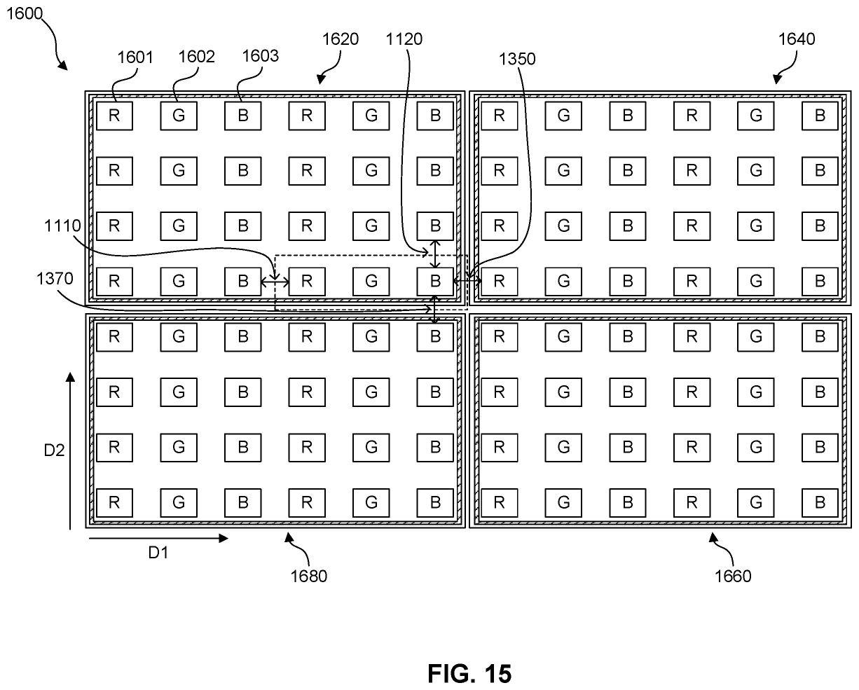

As illustrated in FIG. 15, in an alternative arrangement, a red OLED or a red ILED, a blue OLED or a blue ILED, and a green OLED or a green ILED can be arrayed in the first direction D1 and the second direction D2 to form a multi-color modular display 1600 such that the first intra-modular separation distance 1110 and the second intra-modular separation distance 1120 can be similar or not more than 20% different to the first inter-modular separation distance 1350 and the second inter-modular separation distance 1370. The ability to precisely place ultrathin laser weld lines between the periphery and the active area of a module make the tiling of modules possible to create a modular display appearing seamless to the viewer even across multiple modules.

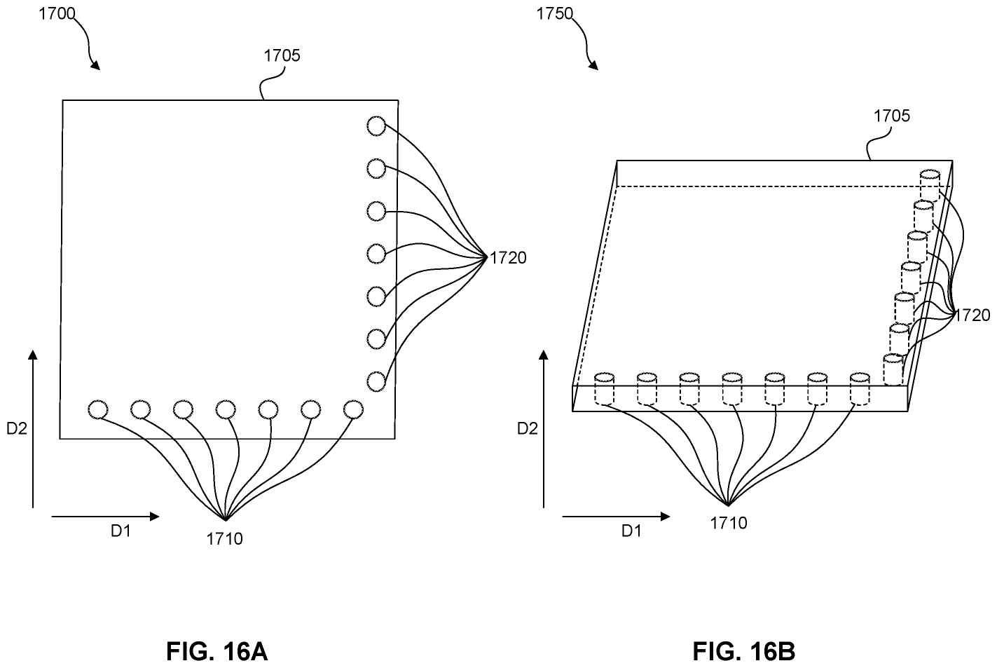

FIG. 16A illustrates a top view of a through-via holed glass substrate 1705 of a passive matrix OLED module 1700, depicting an array of through-via holes. The array of holes provides for a plurality of electrical connections for anode biasing, referred to as anode vias 1710 in the first direction D1 and a plurality of electrical connections for cathode biasing, referred to as cathode vias 1720 in the second direction D2, perpendicular to the first direction D1. The through-via holes may also be referred to as 3D-vias. The through-holes are distributed peripherally and inside the periphery, along one of the linear edges in the first direction D1 and one of the linear edges in the second direction D2. FIG. 16B is a 3D view of the through-via holed glass substrate 1705.

While FIGS. 16A and 16B show anode vias 1710 and cathode vias 1720 disposed along the edge of module 1700, the vias may be placed in any suitable location. For example, overlap between electrical connects and a peripheral weld may be avoided by placing the vias inside a peripheral weld. Inactive area occurs throughout the module, so there is sufficient inactive area such that the vias and any electrical connections between the vias and the active area of a pixel or pixels may be placed inside the peripheral weld. Or, a via may be placed inside a peripheral weld under the active area of a pixel, if such placement does not interfere with the desired emissive properties of a module. For example, for a display that emits light through a second substrate to a viewer, vias may be placed under the active area of the first substrate.

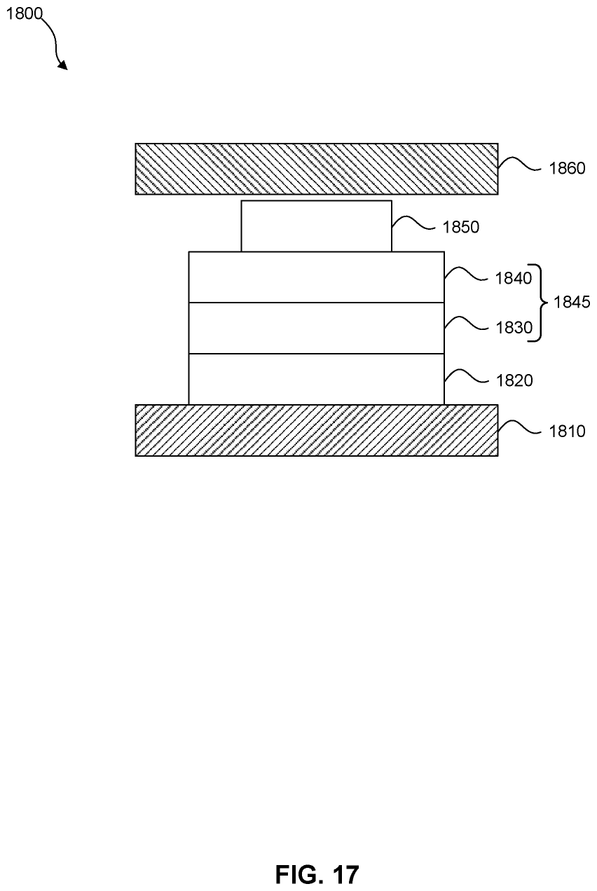

FIG. 17 is a simplified cross-section view of the OLED element. The OLED element, also referred to as an OLED stack, consists of a first transparent substrate 1810 coated with a patterned ITO anode layer 1820, a first organic layer 1830 disposed on and in contact with the patterned ITO anode layer 1820, a second organic layer 1840 disposed on and in contact with the first organic layer 1830, an electrically conducting cathode metal layer 1850 as the cathode contact disposed on and in contact with the second organic layer 1840, and a second substrate 1860 disposed over the cathode metal layer 1850 that can be laser welded to the first transparent substrate 1810 so as to create a hermetic seal between the first transparent substrate and the second substrate.

In some embodiments, the first substrate 1810 comprises a transparent glass substrate, a transparent glass-ceramic substrate, a transparent inorganic film over a glass substrate, a transparent inorganic film over a glass-ceramic substrate and combinations thereof.

In some embodiments, an ITO anode layer 1820 is coated on the first transparent substrate 1810 acting as the anode contact for the device operation. The ITO thin film may be deposited by one of the methods from the listing of, but not limited to, sputter-deposition, e-beam evaporation, thermal evaporation, chemical vapor deposition, physical vapor deposition and a combination thereof. For example, the thin film of ITO may have a thickness of 100 nm, a sheet resistance of 10Ω/□ (ohms/square) and optical transmission of >85% in the visible wavelength range of 400-750 nm.

The first organic layer 1830 and the second organic layer 1840, in combination, may be referred to as the organic stack 1845. The organic stack 1845 includes, but not limited to a hole transport layer, an electron transport layer, an emissive layer, a hole blocking layer, an electron blocking layer, a hole injection layer, an electron injection layer and combinations thereof.

The electrically conducting cathode metal layer 1850, may also be referred to as the cathode contact, is deposited on the organic stack. The cathode metal layer 1850 may be deposited by one of the methods from the listing of, but not limited to, sputter-deposition, e-beam evaporation, thermal evaporation, chemical vapor deposition, physical vapor deposition and a combination thereof.

The second substrate 1860 disposed over the cathode metal layer 1850 comprises a transparent glass substrate, a transparent glass-ceramic substrate, a transparent inorganic film over a glass substrate, a transparent inorganic film over a glass-ceramic substrate and combinations thereof.

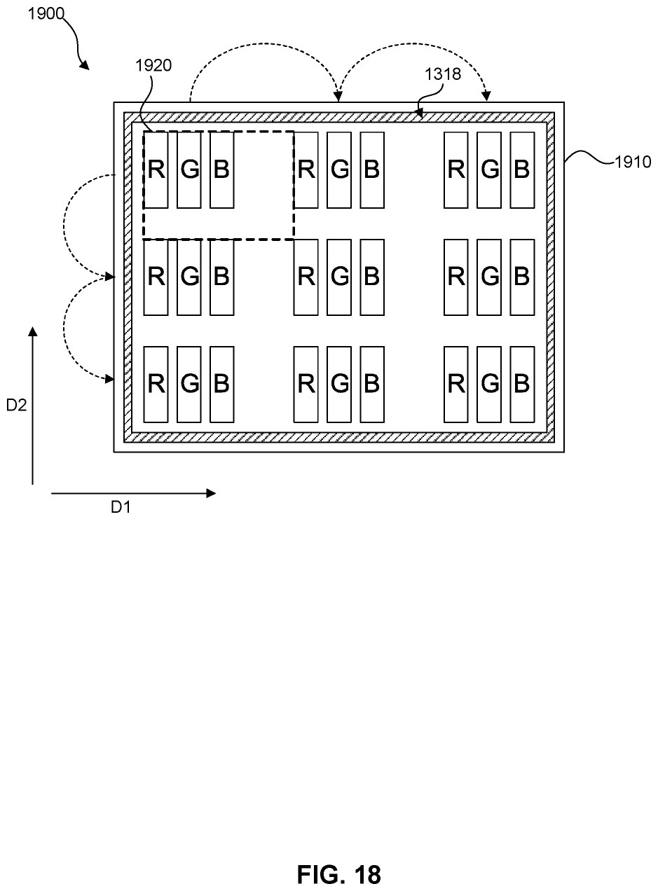

FIG. 18 illustrates a single module R-G-B display 1900 comprising an array of R-G-B pixel 1920 repeated in the first direction D1 and the second direction D2, perpendicular to the first direction D1. The single RGB module 1910 can itself be a discrete display of any theoretical size from the range of 0″ to 0.1″, 0″ to 1″, 0″ to 5″, 0″ to 10″, 0″ to 20″, 0″ to 30″, 0″ to 40″, 0″ to 50″, 0″ to 60″, 0″ to 70″, 0″ to 80″, 0″ to 90″, 0″ to 100″, 0″ to 110″, 0″ to 120″, 0″ to 200″, 0″ to 500″, 0″ to 1000″ or within any range having any two of these values as endpoints.

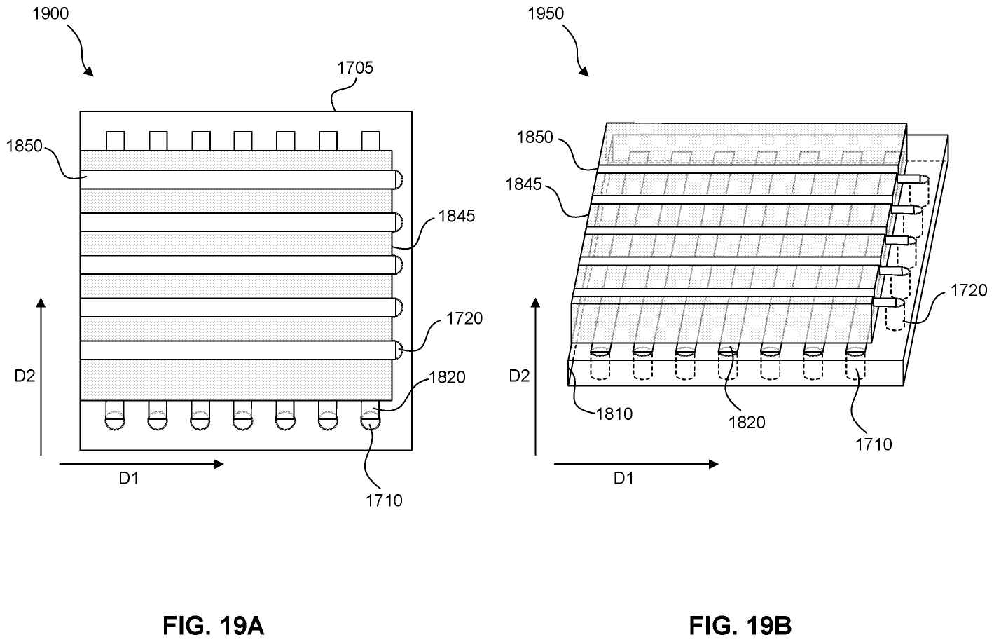

FIG. 19A illustrates a top view of the passive matrix OLED element. The ITO anode layer 1820 may be photolithographically patterned on the first substrate 1705 to form anode race-track patterns such that ohmic contact between individual race-tracks and anode vias 1710 may be achieved. Thin films of organic stack 1845 are disposed on and in contact with the ITO anode layer 1820. The cathode metal layer 1850 may be patterned in a similar race-track pattern as the ITO anode layer 1820, but oriented orthogonal to the anode race-track patterns so as to make ohmic contact with the cathode vias 1720. FIG. 19B is a 3D view of the passive matrix OLED element.

While FIGS. 17-19 illustrate specific OLED structures with a specific electrode configuration, any suitable light emitting structure may be used, including OLED structures different from that illustrated. And, any suitable electrode configuration may be used. Non-limiting examples include OLEDs with a variety of different layers, including separate hole injection, hole transport, electron blocking, emissive, hole blocking, electron transporting and electron injecting layers, and any combination or subset thereof. Non-limiting examples also include different types of light emitting devices, such as QD-LEDS and inorganic LEDs. Non-limiting examples include passive matrix and active matrix displays.

### Example

A module may be constructed using a passive matrix OLED design. When finished, the module may appear to first module 1320, potentially with more pixels. 3D vias may be introduced along the periphery of a 100 mm square Eagle XG (EXG) glass substrate (first substrate) using a laser damage and etch procedure described, for example, in U.S. Pat. No. 9,278,886, entitled “Methods of forming high-density arrays of holes in glass,” and U.S. Pat. No. 9,321,680, entitled “High-speed micro-hole fabrication in glass,” which are incorporated by reference in their entireties. The back side of the resulting hole-plate may be “seeded” with a thin copper deposition at the through-holes, and may then be filled using a copper electro-plating process. There may be two lines of such filled copper through holes—one to supply the anode biasing, and the other to supply the cathode biasing. These filled via lines may be distributed peripherally along the edges of the substrate yet offset from the edges to accommodate laser welding. Other geometries may be used. The resulting 100 mm EXG square substrate with 3D vias may then be cleaned, photo-lithographically patterned, and sputtered with a transparent conducting ITO anode “race-track” array pattern (1 mm wide, 100 nm thick, 10Ω/□). The race-track pattern may be deposited such that ohmic contact between individual race-tracks and 3D-vias is achieved. A simple OLED stack may then be deposited on the anode array pattern consisting of two organic layers: about 60 nm NPD (hole-transport layer), and about 60 nm AlQ3 (electron-transport layer). A “matching” cathode metal array layer (Mg) may be deposited on the organic layers. It may share the same geometric array pattern as the anode array, but be oriented orthogonal to the anode array, and be deposited so as to make ohmic contact with a different row of via through-holes. A top cover plate (second substrate) coated with low melting temperature glass may be brought into an argon glove box, and assembled with the OLED structure. Thin 40 μm laser weld lines may then be applied along the periphery of the cover-plate & OLED assembly, completing the procedure for fabricating the sub-display module.

Four (or more) such modules may be assembled into a larger display assembly. Using exemplary dimensions, four 100 mm square sub-display modules may be tightly packed into a 2×2 assembly by exploiting the thin blank periphery of the sub-display modules. The back of the sub-display modules may use ribbon connectors to facilitate proper interconnectivity biasing. A programmable binary TTL I/O bus may provide input to a driving circuit array that attaches to the anode and cathode ribbon arrays to provide pixel switching. Modules and displays were not actually fabricated.

Embodiments of the present disclosure are described in detail herein with reference to embodiments thereof as illustrated in the accompanying drawings, in which like reference numerals are used to indicate identical or functionally similar elements. References to “one embodiment,” “an embodiment,” “some embodiments,” “in certain embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Where a range of numerical values is recited herein, comprising upper and lower values, unless otherwise stated in specific circumstances, the range is intended to include the endpoints thereof, and all integers and fractions within the range. It is not intended that the scope of the claims be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. Finally, when the term “about” is used in describing a value or an end-point of a range, the disclosure should be understood to include the specific value or end-point referred to. Whether or not a numerical value or end-point of a range recites “about,” the numerical value or end-point of a range is intended to include two embodiments: one modified by “about,” and one not modified by “about.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

As used herein, “comprising” is an open-ended transitional phrase. A list of elements following the transitional phrase “comprising” is a non-exclusive list, such that elements in addition to those specifically recited in the list may also be present.

The term “or,” as used herein, is inclusive; more specifically, the phrase “A or B” means “A, B, or both A and B.” Exclusive “or” is designated herein by terms such as “either A or B” and “one of A or B,” for example.

The indefinite articles “a” and “an” to describe an element or component means that one or at least one of these elements or components is present. Although these articles are conventionally employed to signify that the modified noun is a singular noun, as used herein the articles “a” and “an” also include the plural, unless otherwise stated in specific instances. Similarly, the definite article “the,” as used herein, also signifies that the modified noun may be singular or plural, again unless otherwise stated in specific instances.

The term “wherein” is used as an open-ended transitional phrase, to introduce a recitation of a series of characteristics of the structure.

The examples are illustrative, but not limiting, of the present disclosure. Other suitable modifications and adaptations of the variety of conditions and parameters normally encountered in the field, and which would be apparent to those skilled in the art, are within the spirit and scope of the disclosure.

While various embodiments have been described herein, they have been presented by way of example only, and not limitation. It should be apparent that adaptations and modifications are intended to be within the meaning and range of equivalents of the disclosed embodiments, based on the teaching and guidance presented herein. It therefore will be apparent to one skilled in the art that various changes in form and detail can be made to the embodiments disclosed herein without departing from the spirit and scope of the present disclosure. The elements of the embodiments presented herein are not necessarily mutually exclusive, but may be interchanged to meet various needs as would be appreciated by one of skill in the art.

It is to be understood that the phraseology or terminology used herein is for the purpose of description and not of limitation. The breadth and scope of the present disclosure should not be limited by any of the above-described exemplary embodiments, but should be defined only in accordance with the following claims and their equivalents.

1. An apparatus, comprising:
at least one module, each module comprising:
a first substrate;
a second substrate disposed over the first substrate;
the module having a periphery;
an array of pixels disposed between the first substrate and the second substrate, and inside the periphery, each pixel having an active area and an inactive area;
the array of pixels having a first intra-modular separation distance between the active area of adjacent pixels in a first direction;
a laser weld hermetically sealing the first substrate to the second substrate along a portion of the periphery, such that the laser weld is disposed between the active area of the pixels and the periphery, and the distance between the active area of the pixels and the periphery in the first direction is not more than 50% of the first intra-modular separation distance.

2. The apparatus of claim 1, wherein:
along the portion of the periphery, the entire width of the laser weld is within 500 μm of the periphery.

3. (canceled)

4. (canceled)

5. The apparatus of claim 1, wherein:
along the portion of the periphery, the distance between the laser weld and the active area of the array of pixels is at least 50% of the width of the laser weld.

6. (canceled)

7. (canceled)

8. The apparatus of claim 1, wherein:
along the portion of the periphery, the laser weld has a width less than 500 μm.

9. (canceled)

10. (canceled)

11. The apparatus of claim 1, wherein:
along the portion of the periphery, the distance between the laser weld and the periphery is not more than 50 μm.

12. The apparatus of claim 1, wherein:
along the portion of the periphery, the laser weld directly bonds the first substrate to the second substrate.

13. The apparatus of claim 1, wherein:
the portion of the periphery is the entire periphery.

14. The apparatus of claim 1, wherein:
each module is a rectangle having a first linear edge and a third linear edge in the first direction, and a second linear edge and a fourth linear edge in a second direction perpendicular to the first direction; and
the array of pixels comprises an array of light emitting devices having the first intra-modular separation distance in the first direction, and a second intra-modular separation distance in the second direction.

15. The apparatus of claim 14, wherein:
the first intra-modular separation distance is not more than 2000 μm;
the second intra-modular separation distance is not more than 2000 μm;
along the second and fourth linear edges, the distance between the periphery and the active area of the array of pixels in the first direction is not more than 1000 μm; and
along the first and third linear edges, the distance between the periphery and the active area of the array of pixels in the second direction is not more than 1000 μm.

16. (canceled)

17. (canceled)

18. (canceled)

19. (canceled)

20. (canceled)

21. (canceled)

22. The apparatus of claim 14, wherein:
the at least one module includes a first module and a second module;
the first module is joined to the second module along the second linear edge of the first module and the fourth linear edge of the second module;
an inter-modular separation distance between the active area of a pixel of the first module and the active area of adjacent pixel of the second module in the first direction is not more than 20% different than the intra-modular separation distance of the first module in the first direction and the intra-modular separation distance of the second module in the first direction;

23. The apparatus of claim 14, wherein:
the apparatus comprises a display,
the display comprises:
a two dimensional array of the modules;
a two dimensional array of pixels spread across the two dimensional array of modules, having a plurality of rows in the first direction and a plurality of columns in the second direction;
wherein:
in each row, in the first direction, the separation distance between the active area of each pair of adjacent pixels, whether inter-modular or intra-modular, is not more than 10% different than the average inter-modular separation distance;
in each column, in the second direction, the separation distance between the active area of each pair of adjacent pixels, whether inter-modular or intra-modular, is not more than 10% different than the average inter-modular separation distance;
for each line along which two modules are joined, the separation distance between the active area of adjacent pixels across the line in a first direction perpendicular to the line is not more than 10% different from the average separation distance between the active area of pixels within each of the two modules in the first direction.

24. The apparatus of claim 1, wherein:
the separation distance between the light emitting devices within a pixel in a first direction is 10 to 400 μm.

25. The apparatus of claim 14, wherein:
the module is a rectangle, and each side of the rectangle has a length less than 10 cm.

26. The apparatus of claim 1, wherein:
the apparatus includes only one module, and wherein the one module includes only one first substrate and one second substrate.

27. The apparatus of claim 1, further comprising:
a plurality of electrical connections formed through the first substrate to the array of light emitting devices.

28. The apparatus of claim 1, further comprising:
a plurality of electrical connections from the periphery of the module to the array of light emitting devices.

29. The apparatus of claim 1, wherein:
the light emitting devices are selected from the group consisting of: organic light emitting devices, hybrid quantum dot organic light emitting devices, and quantum dot organic light emitting devices.

30. A method, comprising:
laser welding a second substrate having a periphery to a first substrate by forming at least one laser weld between the second substrate and the first substrate;
wherein:
along at least a portion of the periphery, the entire width of the laser weld is within 500 μm of the periphery; and
an array of light emitting devices is disposed between the first substrate and the second substrate, and inside the periphery.

31. The method of claim 30, wherein:
a thin UV absorbing film on the first substrate or the second substrate absorbs UV laser energy during the welding process.

32. The method of claim 30, wherein:
at least one of the first substrate or the second substrate absorbs sufficient UV laser energy during the laser process to form the laser weld.

33. The method of claim 30, wherein:
the laser weld hermitically seals the array of light emitting devices between the first substrate and the second substrate; and
the laser weld extends along the entire periphery, and is within 500 μm of the periphery along the entire periphery.
